(19) United States
(12) Patent Application Publication
(10) Pub. No.: US 2022/0408673 A1
(43) Pub. Date: Dec. 29, 2022

(54) CLOSED-LOOP, PRESSURIZED AND STERILE, CONTROLLED MICRO-ENVIRONMENT CULTIVATION

(71) Applicant: Hortica Ltd, Tirat Yehuda (IL)

(72) Inventor: Yaron PENN, Rehovot (IL)

(73) Assignee: Hortica Ltd, Tirat Yehuda (IL)

(21) Appl. No.: 17/779,645

(22) PCT Filed: Nov. 25, 2020
(86) PCT No.: PCT/IL2020/051216

§ 371 Date: May 25, 2022

Related U.S. Application Data
(60) Provisional application No. 62/940,260, filed on Nov. 26, 2019.

(51) Int. Cl. A01G 31/06

(52) U.S. Cl. CPC A01G 31/06; A01G 2031/006

(57) ABSTRACT

There is provided a system for controlled and sterile plant growth, comprising: a plant board comprising apertures sized and shaped to accommodate a stalk of a plant, a cover sized and shaped to enclose and seal a top side of the plant board for maintaining sterility of an interior of the cover, air outlets located on a top portion of the cover, a casing sized and shaped to enclose and seal a bottom of the plant board for maintaining sterility of an interior of the casing, air inlet channels having openings facing upwards located on the top side of the plant board, designed to provide laminar air flow into an interior of the cover, wherein the apertures are sized and shaped to provide air flow from the cover to the casing when accommodating the stalk of the plant.

### RELATED APPLICATION

This application claims the benefit of priority of U.S. Provisional Patent Application No. 62/940,260 filed on Nov. 26, 2019, the contents of which are incorporated herein by reference in their entirety.

### FIELD AND BACKGROUND OF THE INVENTION

The present invention, in some embodiments thereof, relates to Controlled-Environment Agriculture (CEA) and, more particularly, but not exclusively, to aeroponic autonomic systems.

Controlled-Environment Agriculture (CEA) aims to optimize plant growing conditions in order to improve plant growth, while minimizing the amount of resources required to grow the plants. Aeroponics is the process of growing plants in an air or mist environment without using soil or an aggregate medium.

### SUMMARY OF THE INVENTION

According to a first aspect, a system for controlled and sterile plant growth, comprises: a plant board comprising a plurality of apertures each sized and shaped to accommodate a stalk of a plant, a cover sized and shaped to enclose and seal a top side of the plant board for maintain sterility of an interior of the cover, a plurality of air outlets located on a top portion of the cover, a casing sized and shaped to enclose and seal a bottom of the plant board for maintaining sterility of an interior of the casing, a plurality of air inlet channels having openings facing upwards located on the top side of the plant board, the plurality of air inlet channel are designed to provide laminar air flow into an interior of the cover, wherein the plurality of apertures are each sized and shaped to provide air flow from the cover to the casing when accommodating the stalk of the plant.

In a further implementation form of the first aspect, further comprising: at least one filter for elimination of odor and/or removal of contamination, the at least one filter is connected to the air outlets outside the cover within an evacuation air channel of air exiting from an interior of the cover, and/or connected to the air inlet channels, before entering the cover within an entering air channel of air being delivered to the interior of the cover.

In a further implementation form of the first aspect, further comprising: a removable sampling cassette with contamination capturing apparatus that captures a sample of contaminants in the interior of the casing and/or the interior of the cover indicating a failure in maintaining sterility therein.

In a further implementation form of the first aspect, further comprising a low-pressure discharge valve located within the casing, the low-pressure discharge valve set at a pressure between an ambient air pressure and a target air pressure of the interior of the cover.

In a further implementation form of the first aspect, further comprising an air delivery system in communication with the plurality of air inlet channels and the plurality of air outlets, the air delivery system operating in a closed loop mode, by circulating air within the plurality of air inlet channels, the cover, and the plurality of air outlets.

In a further implementation form of the first aspect, further comprising a plurality of covers, associated plurality of plant boards, and associated plurality of casings, the air delivery system in communication with a respective plurality of air inlet channels and plurality of air outlets of each of the plurality of covers.

In a further implementation form of the first aspect, wherein a single air delivery system includes a single air outlet tube connected to the plurality of air outlets of each of the plurality of covers, the single air delivery system including a single air inlet tube connected to each of the plurality of air outlets of the plurality of covers.

In a further implementation form of the first aspect, the air deliver system is set to deliver a pattern of airflow into the cover via the plurality of air inlet channels, the pattern of airflow selected according to an association between the pattern of airflow and a target profile of a target type of plant exposed to the pattern of airflow.

In a further implementation form of the first aspect, the target profile includes at least one member selected from a group consisting of: a target biology of the target type of plant, a target physiology of the target type of plant, and a target morphology of the target type of plant.

In a further implementation form of the first aspect, one or more of: (i) the target type of plant is selected from a group consisting of: cannabis, transgenic plants, vegetables, green leaves, and vanilla, (ii) the target biology is selected from a group consisting of protein expression, hormone expression, and chemical profile, (iii) the target physiology is selected from a group consisting of: transpiration, growth rate, yield, and apical control, plant shape, size, leaf number, and number of branches.

In a further implementation form of the first aspect, a spacing and/or a number and/or a pattern of location of the plurality of air inlet channels is selected according to a prediction that plants of a target type exposed to the pattern of airflow from the spacing and/or a number and/or a pattern of spacing of the plurality of air inlet channels obtain a target profile.

In a further implementation form of the first aspect, air delivery system maintains an air pressure within the cover above an air pressure of the casing and maintain the air pressure of the casing above an ambient air pressure.

In a further implementation form of the first aspect, further comprising a plurality of fluid inlet channels having irrigation feeders for delivering a fluid, the plurality of fluid channels are located on the bottom side of the plant board and the opening of the plurality of fluid inlet channel are facing downwards, and a fluid outlet located on a bottom of the casing.

In a further implementation form of the first aspect, further comprising a plurality of fluid inlet channels having irrigation feeders for delivering a fluid, the plurality of fluid inlet channels are located within an inner surface of the casing and the opening of the plurality of fluid inlet channel are facing upwards, and a fluid outlet located on a bottom of the casing.

In a further implementation form of the first aspect, further comprising a fluid delivery system in communication with the plurality of fluid channels and the fluid outlet, the fluid delivery system operating in a closed loop mode, by circulating fluid within the plurality of fluid inlet channels, the casing, and the fluid outlet.

In a further implementation form of the first aspect, further comprising a plurality of covers, associated plurality of plant boards, and associated plurality of casings, the fluid delivery system in communication with a respective plurality of fluid inlet channels and plurality of fluid outlets of each of the plurality of casings.

In a further implementation form of the first aspect, a single fluid delivery system includes a single fluid outlet tube connected to the plurality of fluid inlet channels of each of the plurality of casings, the single fluid delivery system including a single fluid inlet tube connected to each fluid outlet of the plurality of casings.

In a further implementation form of the first aspect, a spacing and/or a number and/or a pattern of spacing of the plurality of fluid inlet channels is selected according to an association between the spacing and/or a number and/or a pattern of spacing of the plurality of fluid inlet channels and a target profile of plants exposed to fluid delivered by the fluid inlet channels.

In a further implementation form of the first aspect, further comprising: a first set of cover sensors located within the cover for monitoring an interior of the cover, and a second set of casing sensors located within the casing for monitoring an interior of the casing, and a controller for independently monitoring the environment within the cover using data obtained from the first set of sensors, and independently monitoring the environment within the casing using data obtained from the second set of sensors, and further comprising a plurality of covers, associated plurality of plant boards, and associated plurality of casings, connected to a central air delivery system and/or a central fluid delivery system, and further comprising a third set of sensors for monitoring at the central air delivery system and/or the central fluid delivery system located at the inlets and/or outlets of the central air delivery system and/or the central fluid delivery system.

In a further implementation form of the first aspect, the controller independently controls a plurality of cover parameters of at least one cover environment control system for controlling the environment within the cover according to the monitored first set of sensors, controls a plurality of casing parameters of at least one casing environment control system for controlling the environment within the casing according to the monitored second set of sensors, and controls at least one air delivery parameter of the central air delivery system and/or controls at least one fluid delivery parameter of the central fluid delivery system, wherein the at least one air delivery parameter includes scheduling of different types of air delivery, and the at least one fluid delivery parameter includes scheduling of different types of fluid delivery.

In a further implementation form of the first aspect, the at least one cover environment control system and the at least one casing environment control system are selected from a group consisting of: air flow controller that controls air flow, heater that controls temperature, air conditioner that controls temperature, supplemental oxygen source that controls amount of oxygen in delivered air, supplemental carbon dioxide source that controls concentration of carbon dioxide in delivered air, humidifier that controls humidity in delivered air, light controller that controls illumination by lights, and a water adjustment system that controls composition and/or scheduling of delivered fluid.

In a further implementation form of the first aspect, the plurality of cover parameters are selected from a group consisting of: air flow, air change, temperature, concentration of oxygen, concentration of carbon dioxide, pressure, illumination, humidity, air composition, and air purity and the plurality of casing parameters are selected from a group consisting of: temperature, pressure, illumination, humidity, contamination, oxygen concentration, carbon dioxide concentration, irrigation water salinity, water pH, nutrient composition, nutrient pH, and nutrient salinity.

In a further implementation form of the first aspect, the first set of sensors are selected from a group consisting of: temperature, humidity, carbon dioxide, air pressure, imaging, and light intensity, and the second set of sensors are selected from a group consisting of: temperature, humidity, air pressure, and irrigation flowrate.

In a further implementation form of the first aspect, the first set of sensors are located on the top side of the board and the second set of sensors are located on the bottom side of the board.

In a further implementation form of the first aspect, further comprising a lighting system for generating light for illuminating an interior of the cover, the lighting system located externally to the cover, and a controller that controls the lighting system to generate an illumination patter predicted to provide a target profile desired for a plurality of plants of a target type.

In a further implementation form of the first aspect, the casing includes an elongated indentation along at least a portion of an internal perimeter thereof, the elongated indentation sized and shaped to accommodate a thickness of the plant board, and to enable insertion and removal of the plant board from the cover.

In a further implementation form of the first aspect, further comprising at least one gasket for sealing the plant board to the cover and to the casing.

In a further implementation form of the first aspect, the casing is sized and shaped to fit on a racking structure comprising a plurality of racks, each rack designed to accommodate a respective casing.

In a further implementation form of the first aspect, the cover is made of a non-rigid material that forms a predefined shape when an air pressure within the cover is set to a target air pressure above an air pressure within the casing and above an ambient air pressure, and the cover is designed to collapse from the predefined shape when the air pressure therein is below the ambient air pressure.

According to a second aspect, a monolithic plant board for controlled plant growth, comprises: the monolithic plant board having a thickness, a top surface, a bottom surface, and a plurality of apertures each sized and shaped to accommodate a stalk of a plant, the top surface of the monolithic plant board sized and shaped for enclosing and sealing a bottom side of a cover for maintain sterility of an interior of the cover, the bottom surface of the plant board sized and shaped for enclosing and sealing a top side of a casing for maintain sterility of an interior of the casing, a plurality of air inlet channels integrated within the monolithic plant board, the plurality of air inlet channels having openings facing upwards located on the top side of the plant board, the plurality of air inlet channel are designed to provide laminar air flow into an interior of the cover.

In a further implementation form of the second aspect, further comprising: a plurality of fluid channels integrated within the monolithic plant board, the plurality of fluid channels having irrigation feeders for delivering a fluid, the plurality of fluid channels are located on the bottom side of the monolithic plant board and the opening of the plurality of fluid channel are facing downwards towards roots of plants located in the interior of the casing.

In a further implementation form of the second aspect, further comprising: a first set of sensors for monitoring an interior of the cover, the first set of sensors are located on the top side of the monolithic plant board and integrated within the monolithic plant board, a second set of sensor for monitoring an interior of the casing, the second set of sensors are located on the bottom side of the monolithic plant board and integrated within the monolithic plant board.

In a further implementation form of the second aspect, a spacing and/or a number and/or a pattern of location of the plurality of air inlet channels of the monolithic plant board is selected according to a prediction that plants of a target type exposed to the pattern of airflow from the spacing and/or a number and/or a pattern of spacing of the plurality of air inlet channels obtain a target profile.

According to a third aspect, a monolithic plant board for controlled plant growth, comprises: the monolithic plant board having a thickness, a top surface, a bottom surface, and a plurality of apertures each sized and shaped to accommodate a stalk of a plant, the top surface of the monolithic plant board sized and shaped for enclosing and sealing a bottom side of a cover for maintain sterility of an interior of the cover, the bottom surface of the monolithic plant board sized and shaped for enclosing and sealing a top side of a casing for maintain sterility of an interior of the casing, and a plurality of fluid channels having irrigation feeders for delivering a fluid, the plurality of fluid channels are located on the bottom side of the monolithic plant board and the opening of the plurality of fluid channel are facing downwards towards roots of plants located below the monolithic plant board in the interior of the casing.

According to a fourth aspect, a device for adjusting a plurality of parameters for controlled plant growth, comprises: at least one hardware processor executing a code for: inputting, into a machine learning model, a target profile desired for a plurality of plants of a target type, the plurality of plants have a same genetic sequence, inputting, into the machine learning model, a plurality of cover parameters of an interior of a cover sensed by a plurality of first sensors located in the cover that is sealed from an ambient environment and from a casing, inputting into the machine learning model, a plurality of a plurality of casing parameters of an interior of a casing sensed by a plurality of second sensors located in a casing that is sealed from the ambient environment and the cover, inputting into the machine learning model, a plurality of environmental system parameter of at least one environmental system sensed by at least one third sensor located within, before, and/or after the at least one environmental system that controls the environment within the casing and/or cover, and adjusting the at least one environment control system that controls the plurality of cover parameters and/or the plurality of casing parameters and/or the plurality of environmental system parameters according to an outcome of the machine learning model, for maintaining the plurality of cover parameters and/or the plurality of casing parameters and/or the plurality of environmental system parameters at a target requirement selected for obtaining the target profile of the plurality of plants growing within the cover and the casing.

In a further implementation form of the fourth aspect, the target profile includes at least one member selected from a group consisting of: a target biology of the target type of plant, a target physiology of the target type of plant, and a target morphology of the target type of plant.

In a further implementation form of the fourth aspect, one or more of: (i) the target type of plant is selected from a group consisting of: cannabis, transgenic plants, vegetables, green leaves, and vanilla, (ii) the target biology is selected from a group consisting of protein expression, hormone expression, and chemical profile, (iii) the target physiology is selected from a group consisting of: transpiration, growth rate, yield, and apical control, (iv) the target morphology is selected from a group consisting of: plant shape, size, leaf number, and number of branches.

In a further implementation form of the fourth aspect, further comprising generating a training dataset including, for each respective sample plant of a plurality of sample plants, labels denoting a measured profile of the respective plant, the plurality of cover parameters associated with the respective sample plant, the plurality of casing parameters associated with the respective sample plant, and the environmental system parameters, and training the machine learning model on the training dataset.

In a further implementation form of the fourth aspect, the training dataset further stores a label indicative of a time interval of a plurality of time intervals during the growing season of the plurality of plants when the respective plurality of cover parameters, the respective plurality of casing parameters, and the environmental system parameters are obtained, and wherein the machine learning model receives as input an indication of a certain time interval during the growing season when the plurality of cover parameters and the plurality of casing parameters are obtained, and the adjusting is obtained for the certain time interval.

Unless otherwise defined, all technical and/or scientific terms used herein have the same meaning as commonly understood by one of ordinary skill in the art to which the invention pertains. Although methods and materials similar or equivalent to those described herein can be used in the practice or testing of embodiments of the invention, exemplary methods and/or materials are described below. In case of conflict, the patent specification, including definitions, will control. In addition, the materials, methods, and examples are illustrative only and are not intended to be necessarily limiting.

Implementation of the method and/or system of embodiments of the invention can involve performing or completing selected tasks manually, automatically, or a combination thereof. Moreover, according to actual instrumentation and equipment of embodiments of the method and/or system of the invention, several selected tasks could be implemented by hardware, by software or by firmware or by a combination thereof using an operating system.

For example, hardware for performing selected tasks according to embodiments of the invention could be implemented as a chip or a circuit. As software, selected tasks according to embodiments of the invention could be implemented as a plurality of software instructions being executed by a computer using any suitable operating system. In an exemplary embodiment of the invention, one or more tasks according to exemplary embodiments of method and/or system as described herein are performed by a data processor, such as a computing platform for executing a plurality of instructions. Optionally, the data processor includes a volatile memory for storing instructions and/or data and/or a non-volatile storage, for example, a magnetic hard-disk and/or removable media, for storing instructions and/or data. Optionally, a network connection is provided as well. A display and/or a user input device such as a keyboard or mouse are optionally provided as well.

### BRIEF DESCRIPTION OF THE SEVERAL VIEWS OF THE DRAWING(S)

Some embodiments of the invention are herein described, by way of example only, with reference to the accompanying drawings. With specific reference now to the drawings in detail, it is stressed that the particulars shown are by way of example and for purposes of illustrative discussion of embodiments of the invention. In this regard, the description taken with the drawings makes apparent to those skilled in the art how embodiments of the invention may be practiced.

In the drawings:

FIG. 1 is a schematic of a plant growing module for controlled and/or sterile plant growth, in accordance with some embodiments of the present invention;

FIG. 2A is a flowchart of a method of using an outcome of a machine learning (ML) model for adjusting parameter for controlled plant growth predicted to generate a target profile of plants of a target type, in accordance with some embodiments of the present invention;

FIG. 2B is a flowchart of a method of generating an ML model for adjusting parameter for controlled plant growth predicted to generate a target profile of plants of a target type, in accordance with some embodiments of the present invention;

FIG. 3 is a block diagram of components of a system including a computing device for controlling environment parameter(s) of an interior environment of a cover and/or a casing and/or of one or more environment control system(s) of a plant growing module, in accordance with some embodiments of the present invention;

FIGS. 4A-4B are schematics of an exemplary air delivery system for delivering air into an interior of one or more covers, in accordance with some embodiments of the present invention;

FIG. 5 is a schematic of an exemplary fluid delivery system for delivering fluid into an interior of one or more casings, in accordance with some embodiments of the present invention;

FIG. 6 is a schematic depicting multiple arrangements of a monolithic plant board, in accordance with some embodiments of the present invention;

FIG. 7 is a schematic depicting a side view of a set of multiple plant growing modules connected to a common central controller and/or common central power source, in accordance with some embodiments of the present invention; and

FIG. 8 is a schematic depicting multiple sets of plant growing modules each connected to a respective common central controller and/or common central power source, in accordance with some embodiments of the present invention.

### DESCRIPTION OF SPECIFIC EMBODIMENTS OF THE INVENTION

The present invention, in some embodiments thereof, relates to Controlled-Environment Agriculture (CEA) and, more particularly, but not exclusively, to aeroponic autonomic systems.

An aspect of some embodiments of the present invention relates to a system (e.g., plant growth housing) for controlled and/or sterile growth of plants and/or other growing therein, for example, medical cannabis, vegetables, fruits, flowers, herbs, fungal algae, and/or insects. The plant growth housing, which is optionally assembled from a plant board (which includes apertures that accommodate a stalk of a plant), a cover designed to enclose and seal a top side of the board, and a casing designed to enclose and seal a bottom side of the board, provides sealed and/or separated interiors within the cover for the canopy of the plants, and within the casing for the roots of the plants. The interior of the cover (sometimes referred to herein as a canopy environment) and the interior of the casing (sometimes referred to herein as a root environment) may be independently monitored by sensors and/or independently controlled by respective environmental control systems optionally under control of a controller. The interiors may be sealed to provide sterility. The sealed and/or separated interiors of the cover and/or canopy are controlled in an objecting and/or reproducible manner, to provide target parameters within the respective environments.

Optionally, components that deliver an air flow channel to and/or from an air delivery system are designed to provide laminar air flow. Air inlet channels having openings facing upwards are located on the top side of the plant board. The air inlet channels are designed to delivery laminar air flow. Outlets may be located on the top portion of the cover, to remove the air from within the interior of the cover. The laminar air flow may be reproduced and/or selected, for example, in contrast to turbulent air flow which is unpredictable.

Optionally, a controller controls the environmental control systems, based on measurements made by sensors, to provide target values of parameters of the interior of the cover and/or casing, which are predicted to provide a target profile of plants of a target type growing in the plant growing module.

An aspect of some embodiments of the present invention relates to a monolithic plant board, which is designed to connect to a casing and/or covering for creating sealed and/or sterile interiors that provide a controlled and/or selected and/or reproducible environment for plants growing therein. The monolithic plant board includes a board with apertures for accommodating a stalk of a plant, and is integrated with one or more or all of the following sub-components (e.g., made by injection molding, 3D printing, or other approaches for manufacturing monolithic structures): air inlet channels designed to provide laminar air flow into an interior of the cover, fluid channels with irrigation feeders for delivery a fluid into an interior of the casing, and one or more sensors for sensing an interior of the casing and/or cover.

An aspect of some embodiments of the present invention relates to systems, methods, an apparatus, a controller, and/or code instructions (stored on a memory and executable by one or more hardware processors) for adjusting parameters of a plant growing housing predicted to provide a target profile of the plants of a target type. A target profile designed for plants of a target type, where the plants have a same genetic sequence (e.g., same DNA) is selected, used for selecting a trained ML model, and/or is inputted into a trained ML model. Parameters of an interior of a cover, parameters of an interior of a casing, and/or parameters of environmental system(s), sensed by sensor(s) are inputted into the trained ML model. The environmental control system(s) is adjusted based on an outcome of the trained ML model, for obtaining and/or maintaining the parameters at a target value (e.g., within a range) selected for obtaining the target profile of the plants growing within the cover and the casing. In at least some implementations, the training of the ML model and/or the feeding of data into the ML model combines environmental parameters from sensors combining physiological and phenotypic parameters from a real time imaging system.

At least some of the apparatus, systems, methods, and/or code instructions (e.g., stored on a memory and executable by one or more hardware processors) address the technical problem of increasing the amount and/or quality of plants grown in an aeroponic autonomic system. At least some of the apparatus, systems, methods, and/or code instructions described herein address the technical problem of obtaining a target profile of the plants grown in the aeroponic autonomic system. At least some of the apparatus, systems, methods, and/or code instructions described herein improve the technology of aeroponic autonomic systems, by enabling growing of a higher amount and/or higher quality of plants. At least some of the apparatus, systems, methods, and/or code instructions described herein improve the technology of aeroponic autonomic systems, by enabling growing plants with a target profile.

In at least some implementations described herein, the solution to the technical problem, and/or the improvement to aeroponic autonomic systems is provided by the design of the cover, board, and casing, which provide a seal of the interior of the cover from the external environment and/or from the interior of the casing, and/or provide a seal of the interior of the casing from the interior of the cover and/or from the external environment. The seal may enable maintaining a sterile environment within the interior of the casing and/or interior of the cover, which protects the growing plants against disease, and/or enables regulating the cover environment and/or the casing environment to generate the target profile, as described herein (e.g., presence of disease may adversely affect the plants so that the target profile is not met even when environmental parameters are selected and/or maintained). The seal may enable maintaining a pressure differential between the interiors and the external environment, as described herein.

In at least some implementations described herein, the solution to the technical problem, and/or the improvement to aeroponic autonomic systems is provided by the maintenance of higher air pressure in the canopy environment than in the root environment, and the higher air pressure in the root environment than ambient pressure. The pressure differentials create an air flow, from the canopy environment where the air is introduced, to the root environment and out to the external environment. The air flow reduces and/or prevents contaminants from entering the canopy environment from the external environment and/or from the root environment, which may create and/or maintains sterile environments within the interior of the casing and/or cover. For example, water and/or nutrients introduced to the roots in the root environment are prevented (e.g., reduced likelihood) from entering the canopy environment and contaminating the canopy of the plants by the pressure differential. The air flow reduces and/or prevents contaminants from entering the root environment from the external environment. The amount of materials introduced into the canopy environment which flow to the root environment via the pressure differential may be negligible. The described pressure differential improves over other existing approaches, where for example, no pressure differential exists at all.

In at least some implementations described herein, the solution to the technical problem, and/or the improvement to aeroponic autonomic systems is provided by the location and/or design of the air flow channels, inlets and/or outlets within the canopy environment, such as on the plant board and/or canopy cover. The air flow channels, inlets and/or outlets are designed and/or positioned to provide controlled laminar air flow, from the bottom of the canopy environment (i.e., from the top of the plant board) towards the top of the canopy environment (i.e., to outlets located towards the top of the canopy cover). Placing the inlet towards the bottom of the canopy environment, where the plants are located, improves control of the air flow existing the outlet of the air channels on the canopy of the plants. For example, laminar air is introduced to the canopy of the plants. The laminar air may then become turbulent (or remain laminar) after flowing past the canopy of the plants, before entering the outlets located towards the upper part of the canopy environment. The laminar air flow provides improved control over other existing approaches, where for example, laminar air flow is not considered and is most likely turbulent, air flow is turbulent, air flow is circular, and/or air flow is introduced from the top of a cover further away from the canopies of the plants, where air flow cannot be controlled and/or where air flow reaches the canopies in a state of turbulent flow. Moreover, the laminar air flow, which is introduced in proximity of the canopies of the plants is uniform and/or repeatable, enabling precise control and/or selection of the air flow in order to obtain a target profile of the plant, as described herein. In contrast, existing approaches do not consider the location of the air inlets and/or direction of air flow and/or type of air flow (e.g., turbulent) as relevant for creating a beneficial environment around the plant's canopy.

In at least some implementations described herein, the solution to the technical problem, and/or the improvement to aeroponic autonomic systems is provided by independent control of environmental parameters of the canopy environment, and independent control of other environmental parameters of the root environment. Each respective environment is independently optimized for the roots and for the canopies of the plants, which improves overall growth of the plant.

In at least some implementations described herein, the solution to the technical problem, and/or the improvement to aeroponic autonomic systems is provided by the machine learning model which is trained on multiple environmental parameters within the root environment and/or within the canopy environment, optionally independently of one another, and trained on a ground truth label indicative of the profile of the plant obtained under the environmental parameters in the respective environments.

In at least some implementations described herein, the solution to the technical problem, and/or the improvement to aeroponic autonomic systems is provided by a monolithic design of the plant board that enables precise placement of the components on the board (e.g., air inlet channels, fluid channels, sensors, irrigation feeders) where the location of the components on the board cannot be changed. The precise location of the components of the board increased the ability of controlling the growing conditions of the plants growing on the board, to obtain reproducible and/or precise growing conditions, to obtain a reproducible target profile, as described herein.

In at least some implementations described herein, the solution to the technical problem, and/or the improvement to aeroponic autonomic systems is provided by the design of placing the lighting system externally to the cover, casing, and/or plant board. The light and/or heat entering the cover from the external lighting system is more precisely controlled, for example, in contrast to a setup where lights are placed within a housing where the plants are growing as is done in other standard approaches.

In experiments conducted by the Inventor of the present disclosure, at closed facilities (indoor), the same varieties were sampled for different growers in both states. Analysis of the profile of each farmer's produce (the flowers after drying) was tested in the same laboratory throughout the annual crop cycles. Inventor discovered that even for the same farmer using the same genetic material (the same plants as if they were taken from the same genetic source), great differences in the profile were found. These differences were also found between different plants in the same growth cycle and even in a single plant. The differences between farmers included a large variation in both overall concentration and concentration ratios. The major differences in the individual farmer's produce were found in the composition and concentration of the terpenes. That is, even if the genetics are the same, small changes in the growing conditions affect the final profile. In other words, a different profile can be obtained by different growth protocols. Inventors discovered that by selecting and/or controlling the growing conditions in the root environment and/or the canopy environment, a desired target profile of the growing plant may be obtained, for example, according to an outcome of a trained ML model, as described herein.

Additional explanations of the addressed technical problems are now discussed:

Controlled environment agriculture (CEA) is the process that allows a plant grower to maintain the proper light, carbon dioxide, temperature, humidity, water, pH levels, and/or nutrients to produce crops year-round. In CEA the focus is in making the most of space, labor, water, energy, nutrients, and capital. The CEA allows the plant grower to reduce the incidences of pests or disease, increase overall efficiency, save resources, and even recycle things such as water or nutrients.

One example of a field for which CEA may be of particular relevance is Urban Cultivation. Urbanization leads to loss of farmland, while at the same time there will be 2 billion more people to feed by 2050, when around 70% of a population of 9 billion will be urban, compared to 50% today. The extent of the increased demand is uncertain, but estimates range up to 70% more crop calories than produced in 2006. To aggravate the problem, climate change is expected to result in farm yield loss. Hence, agriculture faces the challenge of increasing production levels while doing so sustainably. Increasing food growing output in cities can contribute significantly to meeting these challenges.

Another area for which CEA can be relevant is Plant-Made Pharmaceuticals (MPM). Plant-made pharmaceuticals (PMPs) are the result of an innovative application of biotechnology to plants to enable them to produce therapeutic proteins that could ultimately be used to combat illnesses, such as cancer, heart disease, cystic fibrosis, diabetes, HIV, and Alzheimer's disease. Plant-made pharmaceutical production is regulated under stringent requirements of the Food and Drug Administration (FDA) and the U.S. Department of Agriculture (USDA). Additionally, PMP companies adopted guidelines to ensure a uniform code of conduct throughout the industry. Manufacturers have developed standard procedures covering all aspects of production and handling of PMPs, from pre-planting to the delivery of the plant material or the product derived from plant material to processing.

In at least some implementations described herein, the target profile of the plant for PMP may be selected and/or controlled by setting environment parameters of the canopy environment and/or the root environment, optionally based on the outcome of the trained ML model, as described herein.

The global cannabis market is currently estimated at US $ 14.5 billion and is expected to grow to US $ 89.1 billion by 2024 with a growth rate of 37%. The global trend in this market is to move towards utilizing advanced technological methods that enable high quality and repeatability while reducing the costs of the growing process and better utilization of the of produce. There is a growing demand for industrially produced cannabis of excellent quality and high repeatability, both from consumers and pharma, cosmetics, food, and beverage companies. Hence, cannabis growers today want to improve and upgrade their growing process to cope with market trends.

Cannabis growers today face a number of difficulties:

1. Infections—Inventories worth tens of millions of dollars are destroyed each year due to various infections such as molds, fungi and bacteria. These infections also pose real medical risks to cannabis consumers. In at least some implementations described herein, the root environment and/or canopy environment are isolated from the external environment, reducing and/or preventing risk of infection.

2. Reliance on agricultural cycle—Growers are forced to wait until the end of an agricultural cycle (3-4 months) to know whether the growth was successful and meet customer requirements. This situation prevents growers from adjusting the growth protocols in real time during the growth cycle and also impairs their cash flow management as they sell the produce only at the end of the agricultural cycle. In at least some implementations described herein, the target profile of the plant for cannabis may be selected and/or controlled by setting environment parameters of the canopy environment and/or the root environment, optionally based on the outcome of the trained ML model, as described herein.

3. Inability to manage risk and quality control—Agriculture today resembles “traditional” farming in the sense that it is based on experience rather than research. This holding the farmer from implementing quality control procedures in a way that impairs the quality of produce and may create health hazards. Furthermore, risk management is almost non-existent due to difficulty to integrate it with the current agriculture methods.

4. Difficulty in growing crops continuously—Crop growing is done cyclically every three to four months. There is no continuous growth and production, partly due to lack of monitoring, lack of remote control and manpower restrictions. In at least some implementations described herein, parameters of the canopy environment and/or root environment are controlled, enabling continuous growth and/or production.

5. Increasing costs—For example, growing cannabis involves large expenses such as electricity and expensive equipment purchases. These costs are rising all over the world and many growers are now looking for ways to reduce them. In at least some implementations, the control of the environment parameters of the canopy environment and/or root environment optimize electricity, space, and/or water, reducing costs.

6. Inability to meet market needs—A grower typically specializes in a limited number of varieties. It is very difficult to meet market needs for a new breed, as the learning curve is long and requires several growth cycles to reach a sufficient level of expertise.

7. GMP Regulation and Standards as Barriers to Entry into Industrial Markets—Growers targeting high-level manufacturing, such as pharma, food or cosmetics, are forced to invest millions of dollars to upgrade their manufacturing facilities to meet the required standards.

Controlled environments advance plant development, health, growth, flowering and fruiting for any given plant species and cultivars. Aeroponic systems nourish plants only with nutrient-laden mist in a closed or semi-closed environment. The roots of the canopy are separated by a plant support structure. Ideally, the environment is kept free from pests and disease so that the plants may grow healthier and more quickly than plants grown in a medium. However, since most aeroponic environments are not perfectly closed off to the outside, pests and disease may still cause a threat. In at least some implementations described herein, the higher pressure of the canopy environment relative to the root environment and the higher pressure of the root environment relative to the ambient pressure, reduces or prevents pests and/or disease from entering the canopy and/or root environment.

Before explaining at least one embodiment of the invention in detail, it is to be understood that the invention is not necessarily limited in its application to the details of construction and the arrangement of the components and/or methods set forth in the following description and/or illustrated in the drawings and/or the Examples. The invention is capable of other embodiments or of being practiced or carried out in various ways.

Some embodiments of the present disclosure may be a system, a method, and/or a computer program product. The computer program product may include a computer readable storage medium (or media) having computer readable program instructions thereon for causing a processor to carry out aspects of the present disclosure.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing.

Computer readable program instructions described herein can be downloaded to respective computing/processing devices from a computer readable storage medium or to an external computer or external storage device via a network, for example, the Internet, a local area network, a wide area network and/or a wireless network.

The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present disclosure.

Aspects of the present disclosure are described herein with reference to flowchart illustrations and/or block diagrams of methods, apparatus (systems), and computer program products according to embodiments of the disclosure. It will be understood that each block of the flowchart illustrations and/or block diagrams, and combinations of blocks in the flowchart illustrations and/or block diagrams, can be implemented by computer readable program instructions.

The flowchart and block diagrams in the Figures illustrate the architecture, functionality, and operation of possible implementations of systems, methods, and computer program products according to various embodiments of the present disclosure. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

The terms “plant”, and “seedling” may be used interchangeably hereinafter.

The terms “characteristic”, and “profile” may be used interchangeably hereinafter.

The terms “perforated board”, “board, “growing board”, “panel”, “growth cartridge” and “seedling cartridge” may be used interchangeably hereinafter.

The terms “growing module”, “growth module”, aeroponic growth module”, “aeroponic module” and “module” may be used interchangeably hereinafter.

The terms “duct”, “conduit”, “tube”, “channel”, “tunnel” and “pipe” may be used interchangeably hereinafter.

The terms “quick connector”, and “fast connector” may be used interchangeably hereinafter.

The terms “outlet openings”, and “suction openings” may be used interchangeably hereinafter.

The terms “light fixture”, “lighting fixture” and “illumination fixture” may be used interchangeably hereinafter.

The terms “tissue culture propagation center”, “tissue culture reproduction center”, “propagation center”, “reproduction center”, “tissue culture propagation facility” “reproduction facility” and “propagation facility” may be used interchangeably hereinafter.

The terms “growing center” and “growing facility” may be used interchangeably hereinafter.

The terms “compartment” and “chamber” may be used interchangeably hereinafter.

The terms “growing compartment”, “vegetative compartment”, “first compartment”, “canopy compartment” and “growth compartment” may be used interchangeably hereinafter.

The terms “second compartment”, “root compartment”, and “aeroponic compartment” may be used interchangeably hereinafter.

The terms “air cooling unit” and “air cooling battery” may be used interchangeably hereinafter.

The terms “grower”, “farmer” and “breeder” may be used interchangeably hereinafter.

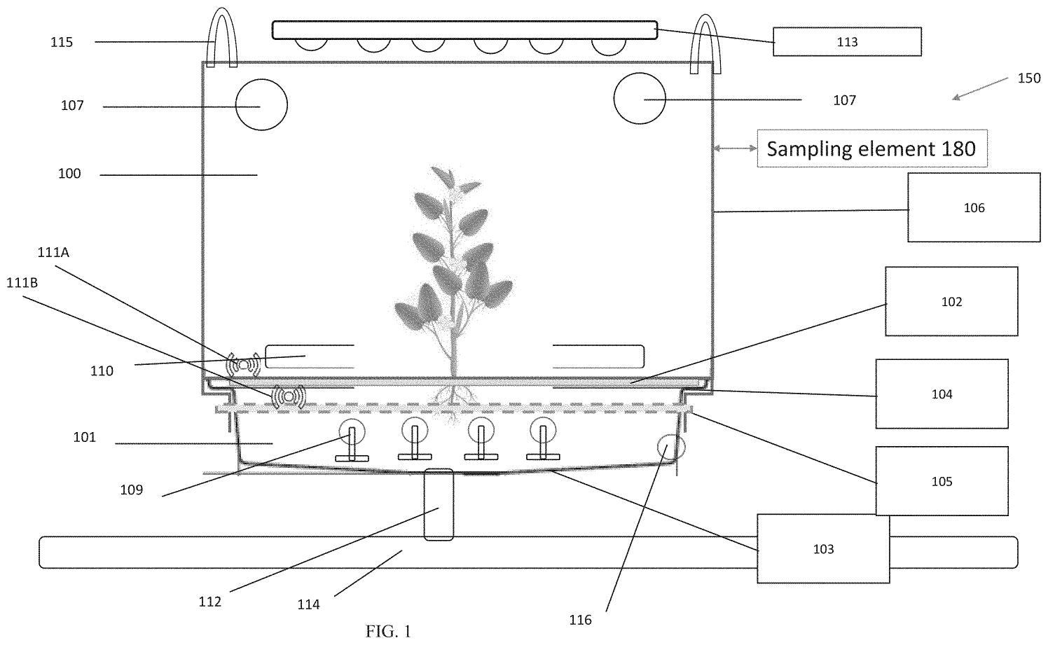

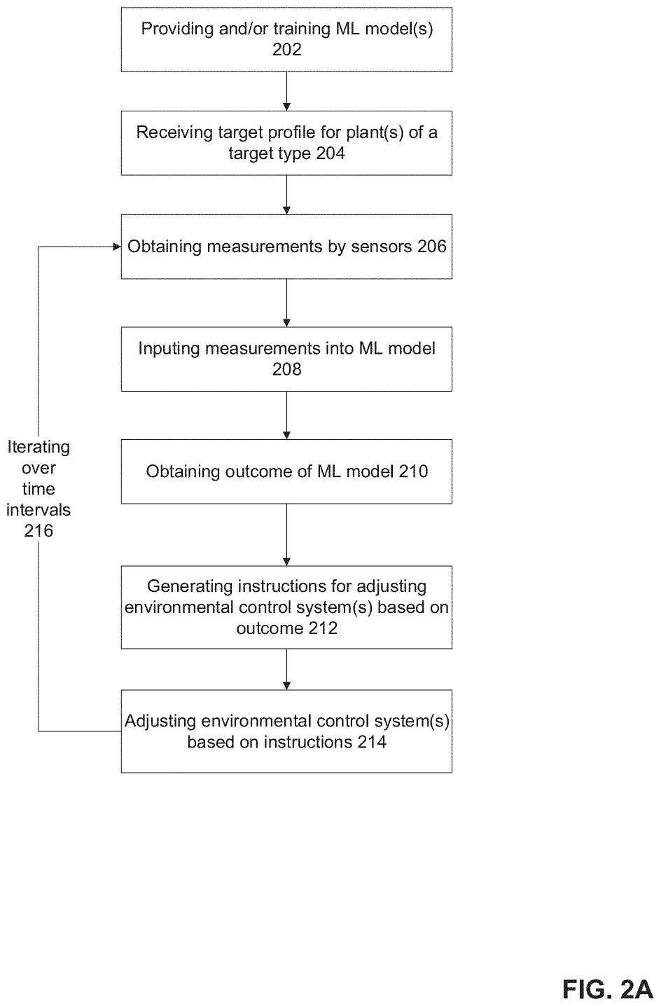

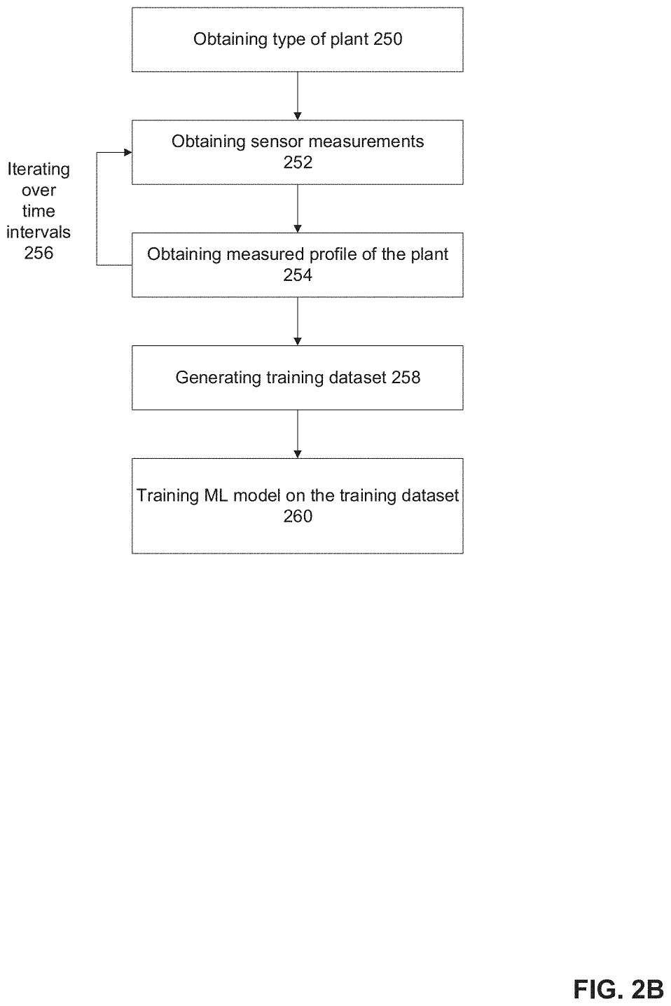

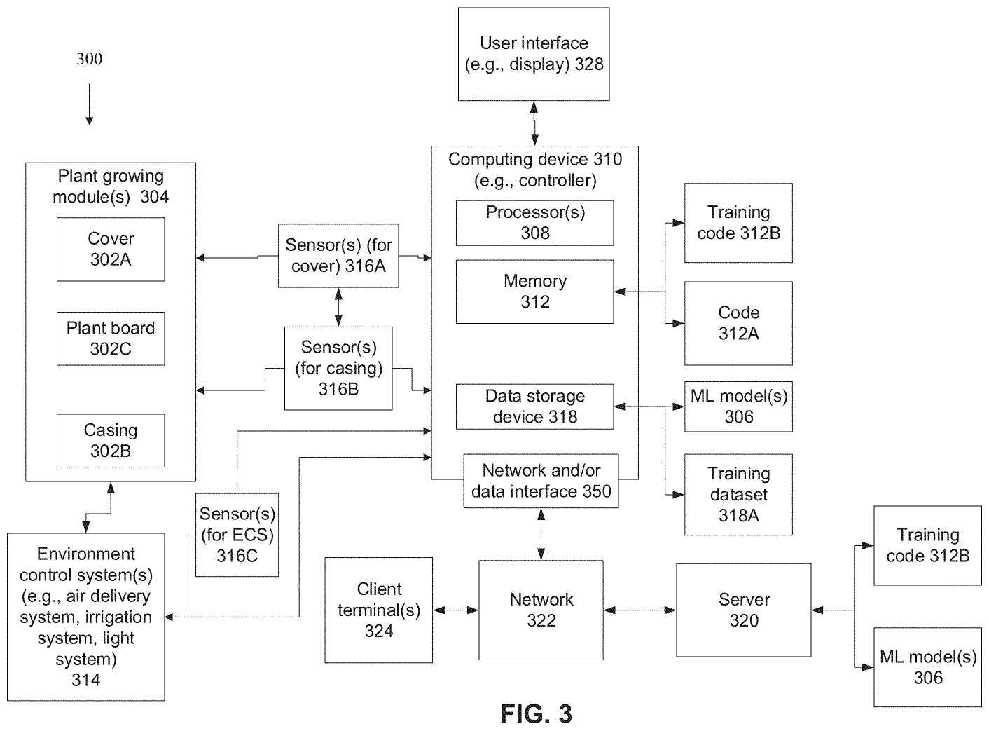

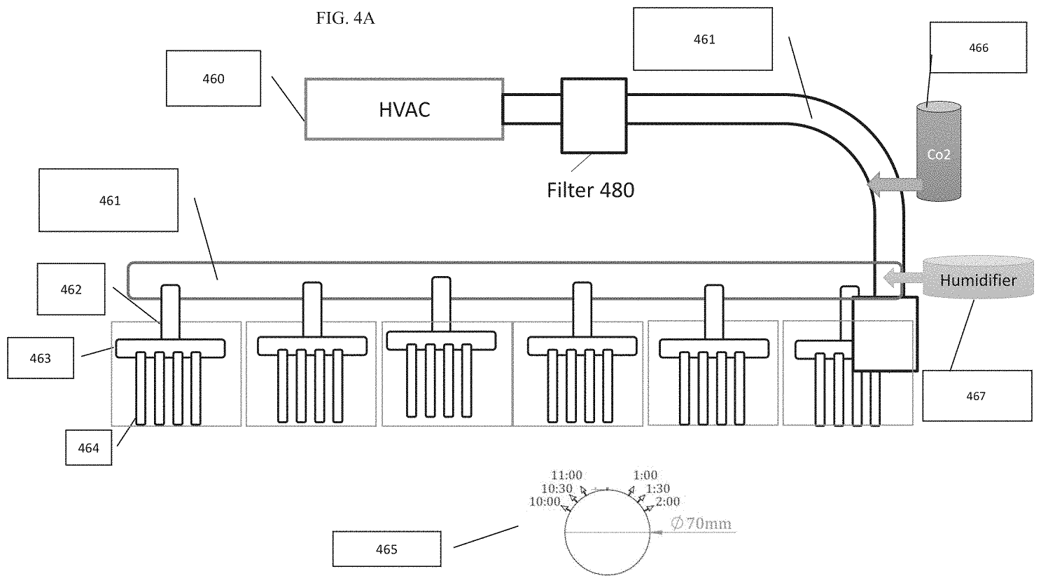

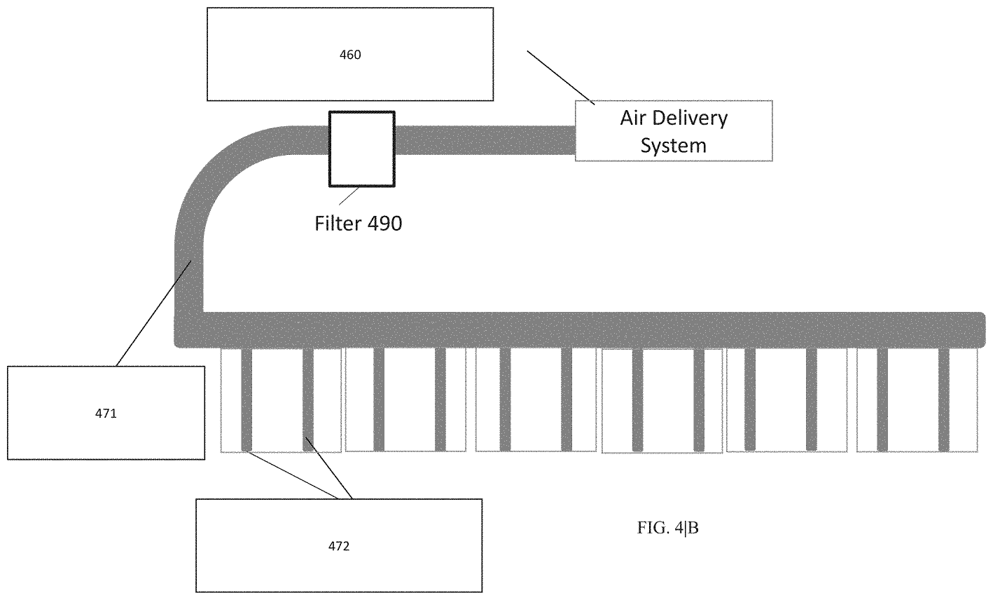

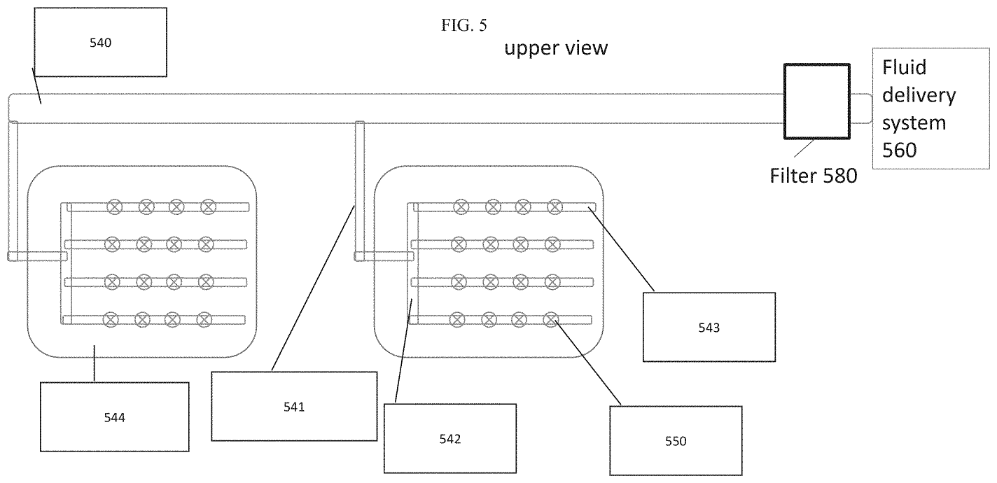

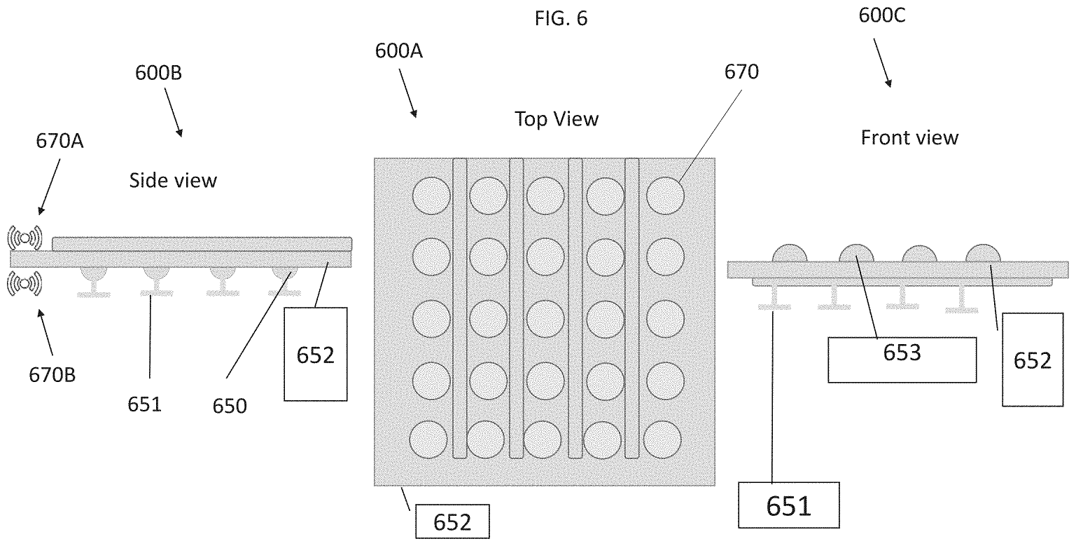

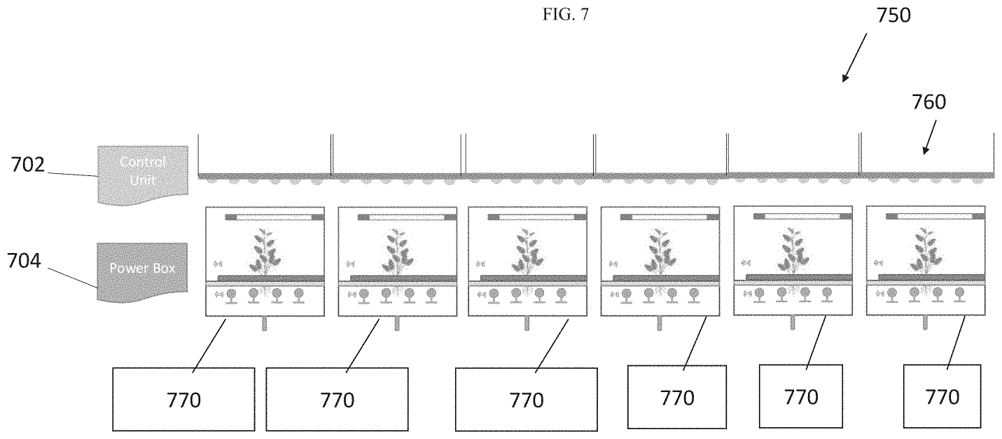

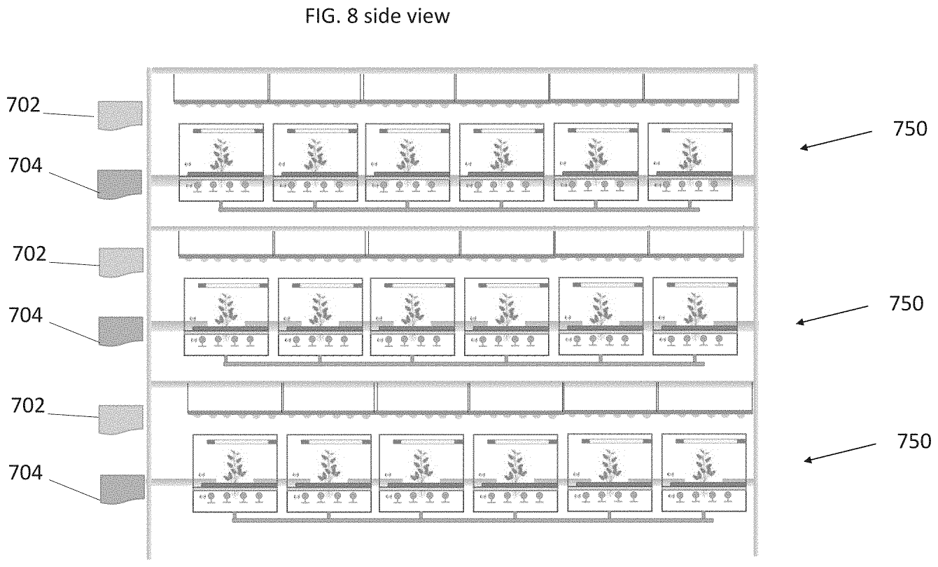

Reference is now made to FIG. 1, which is a schematic of a plant growing module 150 (also referred to herein as plant growing housing 150) for controlled and/or sterile plant growth, in accordance with some embodiments of the present invention. Plant growing module 150 may be used for example, for aeroponic, hydroponic, and/or other methods of growing plants in a controlled environment. Reference is also made to FIG. 2A, which is a flowchart of a method of using an outcome of a machine learning (ML) model for adjusting parameter for controlled plant growth predicted to generate a target profile of plants of a target type, in accordance with some embodiments of the present invention. Reference also made to FIG. 2B, which is a flowchart of a method of generating an ML model for adjusting parameter for controlled plant growth predicted to generate a target profile of plants of a target type, in accordance with some embodiments of the present invention. Reference is also made to FIG. 3, which is a block diagram of components of a system 300 including a computing device 310 (sometimes referred to herein as controller) for controlling environment parameter(s) of an interior environment of a cover 302A and/or a casing 302B and/or of one or more environment control system(s) 314 of a plant growing module (also referred to herein as plant growing housing) 304, in accordance with some embodiments of the present invention. Reference is also made to FIGS. 4A-4B, which are schematics of an exemplary air delivery system 460 for delivering air into an interior of one or more covers, in accordance with some embodiments of the present invention. Reference is also made to FIG. 5, which is a schematic of an exemplary fluid delivery system 560 for delivering fluid (e.g., water, irrigation fluid) into an interior of one or more casings, in accordance with some embodiments of the present invention. Reference is also made to FIG. 6, which is a schematic depicting multiple arrangements of a monolithic plant board 652, in accordance with some embodiments of the present invention. Reference is also made to FIG. 7, which is a schematic depicting a side view of a set 750 of multiple plant growing modules 770 connected to a common central controller 702 and/or common central power source 704, in accordance with some embodiments of the present invention. Reference is also made to FIG. 8, which is a schematic depicting multiple sets 750 of plant growing modules each connected to a respective common central controller 702 and/or common central power source 704, in accordance with some embodiments of the present invention.

Referring now back to FIG. 1, components of plant growing module 150 are designed to create separate and/or independently monitored and/or sterile and/or independently controlled environments for the canopies (may be interchanged with the term vegetative part) of plants, sometimes also referred to herein as canopy environment 100 (may be interchanged with the term vegetative environment), and for the roots of the plants, sometimes also referred to herein as root environment 101. The canopy environment and root environment may be hermetically sealed from one another and from the outside environment. Optionally, limited space is provided between stalks of plants and an inner surface of an aperture of a plant board 102 where the stalk of the plant is located, for example, to provide air flow from the canopy environment into the root environment for pressure regulation, as described herein. The independent monitoring and/or independent control of the each of the canopy environment and the root environment enable standardization across plants of the same genetic source and across growth cycles along the year, optionally to product a target composition of the plants, as described herein.

Plant growing module 150 includes a plant board 102, a cover 106 sized and shaped to enclose and seal a top side of plant board 102, and a casing 103 sized and shaped to enclose and seal a bottom of plant board 102. Cover 106 may be designed to provide and/or maintain sterility in interior thereof. Casing 103 may be designed to provide and/or maintain sterility in interior thereof.

Plant board 102 includes apertures, each sized and shaped to accommodate a stalk of a plant. Optionally, wherein the apertures are each sized and shaped to provide fluid (e.g., air) flow from cover 106 to casing 103 when accommodating the stalk of the plant. Alternatively, the apertures are designed to seal around the stalk of the plant for sealing fluid flow between the cover 106 and the casing 103, for example, including a seal, rubber ring, and/or sponge. The diameter of apertures may be, for example, about 1-4 cm, or about 2-3 cm, or other values. Apertures may be located, for example, in parallel rows, for example, 6 rows of 5 apertures, or 3 rows of 10 apertures, or other combinations. The arrangement of apertures may be selected to increase likelihood of obtaining a target profile, as described herein. Alternatively or additionally, board 102 includes apertures dedicated to provide air flow from interior of cover 106 to interior of casing 103. Such dedicated apertures are not used for plants. The diameter of the dedicated apertures may be smaller than apertures designed to accommodate stalks of plants.

The dimension of board 102 may be, for example, about 1 meter×1 meter, or about 50 centimeters (cm)×1 meter, or other dimensions selected, for example, according to a number of desired plants growing therein, density of plants, ability to control environment within cover 106 and/or casing 103. The thickness of board may be, for example, between 2-5 cm, or 1-3 cm, or 3-6 cm, or other ranges. The dimensions of casing 103 and/or cover 106 correspond to the dimension of board 102, for assembling the plant growing module 150, as described herein.

Board 102 may be made of, for example, plastic and/or stainless steel. Optionally, board 102 is made out of a non-absorbable material that may be disinfected and/or sterilized, to reduce risk of contamination.

The canopies of the plant are located within an interior 100 of cover 106, sometimes also referred to herein as canopy environment 100. Stalks of the plants are located within an interior 101 of casing 103, sometimes also referred to herein as root environment 101.

In some embodiments, plant growing module 150 may be assembled by placing plant board 102 on an optional indentation 104 located at an upper region of casing 103. Indentation 104 may be elongated indentation along at least a portion of an internal perimeter of casing 103. Elongated indentation 104 may be sized and shaped to accommodate a thickness of the plant board 102, and to enable insertion and/or removal of the plant board from the cover 106. Board 103 may form a bottom of a drawer insertable into indentation 104, that when fully inserted seals interior of casing 103 from interior of cover 106.

Cover 106 isolates the interior thereof from the external environment. Cover 106 may be fastened to casing 103 after board 102 is assembled and sealed, for example, by gasket 105, by rubber, claspers, and/or other component that create an air separation between the interior of cover 106 and the interior of casing 103 from the ambient environment. The isolation of interior of cover 106 from interior of cover 106 creates canopy and/or root environments with hyper pressure relative to the external ambient environment.

Optionally, board 102 may be initially (i.e., before being assembled by connecting to casing 103 and/or cover 106) wrapped with a bag for keeping seedlings planted therein in isolation from environmental contaminants. One or more knifes may be provided to rip the bag while the board is being assembled. Optionally, one or more sheets are used to wrap the plant board when board is removed and/or disassembled rom casing 103 and/or cover 106 for keeping the harvest isolated from the environment. The bag and/or the sheet may include one or more antimicrobial agent.

Cover 106 may include an opening, for example, a door and/or by a sealed zipper, that allow opening for access to plants. For example, the opening is used for inserting the board, with the opening being kept closed throughout the entire growth phase, unless in cases of emergency or destruction of the crop. This is to avoid variations in the conditions inside such as the airflow around the canopies of the plants.

Cover 106 may be sized to have an interior volume of about 1 cubic meter or any other size.

Optionally, casing 103 is sized and/or shaped to fit on a racking structure that includes multiple racks. Each rack is designed to accommodate a respective casing 103. The racking structure is designed to accommodate multiple plant growing modules 150. The multiple plant growing modules 150 may be centrally controlled, as described herein.

Cover 106 may be placed over casing 103. Alternatively or additionally, cover 106 is designed to fit within indentation 104 of casing 103. Alternatively, or additionally, a bottom region of cover 106 includes indentation 104. Plant board 102 is placed on indentation of cover 106. Casing 103 may fit into indentation 104 of cover 106.

An optional gasket 105, optionally located along indentation 104 may form a seal (optionally hermetic seal against fluid flow such as air and/or water) between interior 101 of casing 103 and interior 100 of cover 106.

The depth of indentation 104 may be sized according to a thickness of board 104 and/or thickness of cover 106 and/or thickness of casing 103, such as to create a seal around gasket 105, for example, about 2-7 cm, or about 2-5 cm, or other values.

Cover 106 includes openings (e.g., on a bottom region close to board 102) to accommodate multiple air inlets channels 111 to provide air into the interior of cover 106. Cover 106 may include a sleeve opening that wraps the air supply pipe and/or is sealed by a clamp and/or by a quick connector. The inlet air channels 111 bring treated air coming from an air supply device.

Air inlet channels 111 may include one or more air channels (e.g., tubes, pipes) located on the top side of board 102. Air inlet channels 111 may include one or more openings facing upwards. Air inlet channels 111 and/or other air components are designed may be designed to provide laminar air flow into cover 106, for example, having a smooth interior surface and/or a small diameter and/or controlled rate of air flow delivery (e.g., liters per minute) to reduce risk of turbulent air flow. Air inlet channels 111 may be made of flexible and/or rigid material, for example, leather and/or plastic. The spacing and/or number and/or pattern of location of air openings may be selected to provide repeatable and/or controllable air flow, for example, based on an association between spacing and/or number and/or pattern of location of air openings and a target profile of the plants exposed to the pattern of air flow. For example, air openings may be disposed at equal distance, non equal or at a gradient distance leading to uniform or non-uniform airflow along the air inlet channels (sleeves). The pattern of the airflow may vary and be adjusted as per plant's number and/or as per plant's needs (i.e., different plant types or plant number will produce a different demand for air distribution, as described herein).

Cover 106 includes multiple air outlets 107, through which air exists interior of cover 106. Air delivered into interior of cover 106 via air inlet channels 111 exist the interior of cover 106 via outlets 107. Air outlets 117 may be connected to one or more outlet units (e.g., pump) that draw air from the interior of cover 106 to the air supply system.

Optionally, a low-pressure discharge valve 116 is located within the casing 103. The low-pressure discharge valve 116 may be set at a target pressure between an ambient air pressure and a target air pressure of cover 106.

Exemplary air flow, delivered by an air delivery system (as described herein) is as follows: air enters interior of cover 106 via openings of air inlet channels 111. Some air in interior of cover 106 flows out of cover 106 via air outlet 107. Other air in interior of cover 106 flow into casing 103 via apertures of board 102. When the pressure in casing 103 exceeds the target pressure of low-pressure discharge valve 116, excess air exists casing 103 via low-pressure discharge valve 116. The described exemplar air flow and components that direct and/or deliver the air flow help ensure that the pressure of the interior of cover 106 is maintained higher than the pressure of the interior of casing 103 and higher than ambient pressure, and the pressure of the interior of casing 103 is maintained higher than ambient pressure and lower than the pressure of interior of cover 106. The pressure gradient may help serve as an air barrier, preventing contaminants, cross-contamination, and/or cross-pollination between plants and/or the external environment. In addition, the pressure gradients may act as an air lock, preventing or reducing likelihood of moisture and/or contaminants flowing in a backwards direction, from the external environment to the interior of casing 103, and/or from interior of casing 103 to interior of cover 106.

Moreover, the pressure gradient may be repeatable and/or maintained at desired settings, for example, for obtaining plants meeting the target profile, as described herein.

Optionally, plant growing module 150 includes multiple fluid inlet channels that supply fluid to irrigation feeders 109 (e.g., foggers, sprinklers, mist generators, and/or drippers) for delivering a fluid into interior of casing 103, for example, water with optional nutrients. Optionally, the fluid channels and/or irrigation feeders 109 are located on the bottom side of the plant board 102. The opening of the fluid inlet channels and/or the irrigation feeders 109 may be facing downwards. Alternatively or additionally, the fluid channels and/or irrigation feeders 109 are located on the inner surface of casing 103. The opening of the fluid inlet channels and/or the irrigation feeders 109 may be facing upwards and/or towards the interior of the root environment formed by the interior of casing 103.

Optionally, in an aeroponic implementation of plant growing module 150, each irrigation feeder 109 (e.g., fogger) is located at or approximately at the center between the plants and may include one to multiple outlet-nozzles distributed to enable a uniform water environment to the roots. For other implementations, such as hydroponic, sprinklers and/or drippers may be used.

The spacing and/or number and/or pattern of location of irrigation feeders 109 may be selected to provide repeatable and/or controllable fluid flow, for example, based on an association between spacing and/or number and/or pattern of location of irrigation feeders 109 and a target profile of the plants exposed to the pattern of fluid flow. For example, irrigation feeders 109 may be disposed at equal distance, non equal or at a gradient distance leading to uniform or non- uniform fluid flow along the fluid inlet channels. The pattern of the fluid flow may vary and be adjusted as per plant's number and/or as per plant's needs (i.e., different plant types or plant number will produce a different demand for irrigation, as described herein).

Optionally, a fluid outlet 112 is located on a bottom of casing 103, for draining excess fluid delivered by irrigation feeders 109. When multiple plant growing modules 150 are implemented, respective fluid outlets 112 may connect to a central drain pipe 114. Optionally casing 103 is shaped so that fluid outlet 112 is located at a local point thereof, for example, the bottom part of casing 103 is concave and/or tapered.

Optionally, lights 113 are located externally to cover 106, for example, light emitting diodes, fluorescent, incandescent. Optionally, lights 113 are cooled using water. Water efficiently transfers heat from lights 113 to be cooled and/or re-used for heating. This arrangement facilitates control temperature on the plant leaves, which may be a significant parameter for obtaining the target profile. Lights 113 may include an array of water cooled lighting fixtures per square meter (e.g. 5, 7, 10, 12, or other number). Chip on Board (COB) LEDs producing color temperature of 3500k may be installed in the lighting fixtures 113. Each water cooled lighting fixture 113 may operate at for example 50-75 watts per hour or other values. Temperature of lights 113 measured by Inventors in experiments was around 25 degrees Celsius, which allowed the lighting fixtures 113 to be installed less than 10 cm away from the cover 106, intensifying the light flux to the canopies of the plants with low risk of affecting temperature inside cover 106. Additionally, the low working temperature results in higher efficiency compared with common working temperature of about 75 degrees Celsius. Moreover, the heat removed from the lighting fixtures by the cooling water may be used for heating the air supplied to the interior of cover 106. The controller may adjust one or more of the following parameters of the lights 113: intensity, spectrum, and illumination times.

Plant board 102 and/or casing 103 may be made of a material that is opaque to light, to avoid or reduce light from reaching the roots of the plants.

Cover 106 may be made from, for example, PVC, fiber glass, and/or combination thereof. Optionally, cover 106 is made of a non-rigid material that forms a predefined shape when an air pressure within the cover is set to a target air pressure above an air pressure within the casing and above an ambient air pressure. For example, cover 106 may be made of flexible plastic, and may expand into a square, rectangle, circular, oval, and/or other shapes like a balloon. Cover 106 may collapses from the predefined shape when the air pressure therein is below the ambient air pressure. When the pressure within cover 106 starts to decrease (e.g., leak from the sealed interior of cover 106) but is still above the ambient air pressure, cover 106 may not fully collapse, but slowly lose its shape, providing a visual indication to a user that the air pressure inside cover 106 is falling and/or providing a time buffer before the pressure falls to a minimal value. Alternatively, cover 106 is made of a rigid material.

Cover 106 may be made of, for example, different types of material, transparent semi-transparent, disposable and/or reusable with or without an opening.

Optionally, at least a portion of a top part of cover 106 is made from ultra-clear material (e.g., flexible, hard) to enable light generated by lights 113 located externally to cover 106 to enter into interior of cover 106, for example, for providing light to the plants, photography of the plants, visual monitoring. Shading screens may be used to reduce the amount of sunlight entering cover 106. Alternatively or additionally, smart material may be used whose light transmission properties are altered when voltage, light, and/or heat is applied.

Optionally, one or more loops 115 are connected to cover 106. Loops 115 may provide a defined shape for cover 106, and/or may be used to raise and/or remove cover 106. Optionally, cover 106 includes a skeleton, excludes a skeleton, or without a skeleton but with hanging loops 115 from above in order to prevent cover 106 from collapsing on the plants when cover 106 is made from the non-rigid material and is disconnected from air supply.

Optionally, one or more sensors 111A-B are located within casing 103 and/or cover 106. Optionally, a first set of sensors 111A (sometimes referred to herein as cover sensors) are located within the cover 106 for monitoring an interior of the cover. Sensors 111A are optionally located on the top side of plant board 102. Exemplary sensors 111A include one or more of: temperature, humidity, carbon dioxide, air pressure, and light intensity. Alternatively or additionally, a second set of sensors 111B (sometimes referred to herein as casing sensors) located within the casing for monitoring an interior of the casing. Sensors 111B are optionally located on the bottom side of plant board 102. Exemplary sensors 111B include one or more of: temperature, humidity, air pressure, and irrigation flowrate.

Optionally, each sensor 111A-B has a feed-in wire and/or a read-out wire collected to bundle the sensors. Sensors wires may be collected into one common cable bundle. A common cable connector may be fastened by a screw or by a quick connector. The connector may be integrated to the board 102 and/or may be separated and/or attached to the board 102. Alternatively or additionally, sensors 111A-B include a wireless transceiver for wirelessly transmitting collected data, for example, over a network, such as in an Internet of things (IoT) implementation.

Optionally, a mesh having dimensions corresponding to the dimension of board 102 is positioned to span the interior of casing 103, located between bottom of casing 103 and bottom of board 102. Mesh may be made of flexible, soft, and/or rigid material. The mesh is designed to support roots and/or enable the roots to pass through the mesh.

Optionally, plant growing module 150 includes a removable sampling element 180 (e.g., cassette) with contamination capturing apparatus that captures a sample of contaminants in the interior of the casing and/or the interior of the cover indicating a failure in maintaining sterility therein. The removable sampling element 180 may be located, for example, in the wall of cover 106, in the wall of casing 103, and/or in board 102. Alternatively or additionally, sample element 180 is implemented as a non-removable sensor. Optionally, an indication of contamination is fed to the controller, which may trigger an alert (e.g., flashing light, message to a mobile device, log entry in a server) and/or attempt to solve the contamination problem by adjusting the environmental systems, for example, checking if the pressure inside the cover is high enough.

Referring now back to FIG. 2A, at 202, an ML model is provided and/or trained.

Multiple ML models may be provided and/or trained, for example, each ML model is trained for a different type of plant. One ML model may be selected from the multiple ML models according to the type of plant being grown. Alternatively, a single ML model is provided and/or trained for multiple different types of plants, in which case the type of plant may be provided as input into the ML model.

Optionally, one or more ML models are provided and/or trained for a certain target profile desired for the plants of the target type. One ML model may be selected from the multiple ML models according to the target profile of the type of plant being grown. Alternatively, a single ML model is provided and/or trained for multiple different target profiles for a certain type of plant and/or different types of plants, in which case the target profile and/or type of plant may be provided as input into the ML model.

An exemplary process for training the ML model is described with reference to FIG. 2B.

At 204, a target profile desired for the plants of a target type, which are growing in the plant growing module that includes the cover, casing, plant board, connected to one or more environmental control systems, and monitored by sensors, may be received, for example, selected by a user (e.g., via a user interface such as a graphical user interface (GUI), automatically determined, and/or obtained from a file stored on a memory. Alternatively, the ML model is selected according to the target profile.

The plants of the target type have a same genetic sequence. The plants originate from the same genetic source, and have the same genetic material, for example, the same DNA sequence. For example, from parent plants that are produced after an R&D process having most or all of their DNA being homozygous, a process sometimes referred to as stabilizing the parents. Because the parents are stabilized, the produced Fl offspring are genetically uniform, containing the same genetic material. The plants may all be of a same isogenic line, i.e., from a same parent, having DNA identical to the parent. Alternatively, the plants have the same genetic sequences at genes that express themselves, with non-similar genetic sequences at non-coding regions. Alternatively or additionally, the genetic difference (e.g., difference in DNA sequences) between the plants are not significant, for example, not resulting in expression of measurable traits such as phenotype, color, size, and virus resistance.

Examples of target type of plant include: cannabis, transgenic plants, vegetables, green leaves, vanilla, and/or other based on a defined plant classification system.

The target profile may be based on quantifiable and/or measurable object parameters, for example, measured by a mass spectrometer, chemical analysis, genetic analysis, weight, height, automated analysis of digital images of the plants, and the like.

The target profile may include one or more of: a target biology of the target type of plant, a target physiology of the target type of plant, and a target morphology of the target type of plant.

Examples of the target biology include: protein expression, hormone expression, composition and concentration of secondary metabolite (e.g., terpene), and profile.

Examples of the target physiology include: transpiration, growth rate, yield, and apical control.

Examples of the target morphology include: plant shape, size, leaf number, and number of branches.

At 206, measurements made by one or more sensors are obtained.

Exemplary sensors and measurements include one or more of: cover parameters of an interior of a cover sensed by a first set pf sensors located in the cover that is sealed from an ambient environment and from a casing, casing parameters of an interior of a casing sensed by second sensors located in a casing that is sealed from the ambient environment and the cover, and environmental system parameter of at least one environmental system sensed by one or more third sensors located within, before, and/or after the at least one environmental system that controls the environment within the casing and/or cover. Sensor measurements may include images of the plant, of one or more wavelengths (e.g., as described herein).

Exemplary sensors, exemplary parameters, and exemplary environmental systems are described herein.

At 208, the measurements obtained from the sensors are inputted into the ML model.

Optionally, the target profile is inputted into the ML model. Alternatively, the ML model is for a preselected target profile.

Optionally. The type of plant is inputted into the ML model. Alternatively, the ML model is for a preselected type of plant.

Optionally, an indication of a time interval within the growth cycle of the plant is inputted into the ML model, for example, degree days, current day from start of the growth cycle, and/or calendar day.

At 210, an outcome of the machine learning model is obtained. The outcome may be an indication for adjusting the at least one environment control system that controls the cover parameters and/or the casing parameters and/or the environmental system parameters, for maintaining the plurality of cover parameters and the plurality of casing parameters at a target requirement selected for obtaining the target profile of the plurality of plants growing within the cover and the casing

At 212, instructions for adjusting the at least one environment control system may be generated based on the outcome of the ML model, for example, output signals and/or code may be generated, for example, by the controller.

At 214, the at least one environment control system that controls the over parameters and/or the casing parameters and/or the environmental parameters is adjusted according to the instructions. The adjustment is for maintaining the cover parameters and/or the casing parameters and/or the environmental parameters at a target requirement selected for obtaining the target profile of the plants of the target type growing within the cover and the casing. The target requirement may denote a tolerance range within which the respective parameter may vary.

At 216, one or more features described with reference to 206-214 may be iterated over multiple time intervals, for example, per week, per day, per hour, or other time interval, for example, according to the plant type and/or length of growing season.

In each iteration, the machine learning model receives as input an indication of the current time interval during the growing season when the cover parameters and/or the casing parameters and/or the environmental parameters are obtained. The adjusting is performed for the current time interval. Alternatively, a time sequence is generated of the parameters obtained at multiple time intervals (e.g., once a day for a week), and the sequence is inputted into the ML model.

Referring now back to FIG. 2B, at 250, a type of plant, which is growing in the plant growing module that includes the cover, casing, plant board, connected to one or more environmental control systems and monitored by sensors, is obtained. There may be multiple plants, of the same type, and/or of different types.

Within each sample plant growing module (i.e., of an assembled plant board, cover, and casing, as described herein), all plants may be of a same type and/or have a same genetic material (e.g., same DNA from same source).

At 252, for each sample plant growing module, the cover parameters and/or the casing parameters and/or the environmental parameters are obtained from measurements made by sensors, as described herein.

At 254, for each sample plant growing module, a label denoting a measured profile of one or more plants growing therein is created.

At 256, one or more of 252 and 254 may be iterated over multiple time intervals, optionally over the growing season of the plants.

For each iteration, a label indicative of a current time interval during the growing season of the sample plants is obtained. The current time interval is associated with the obtained parameters (i.e., cover, casing, and/or environmental), and/or with the measured profile.

It is noted that the profile may be measured at the same time as the parameters, or at a different time than the parameters. For example, the profile may be measured at the end of the growing season, while the parameters are measured every day during the growing season.

At 258, a training dataset is generated. The training dataset stores one or more records, each including one or more of: an indication of the type of plant, the measured profile, the casing parameters, the cover parameter, the environmental parameters, and/or a time interval during the growing season.

The training dataset may store a time sequence, for example, for each sample plant, a time sequence of the parameters and/or profile measurements obtained at multiple time intervals during the growing season.

At 260, the machine learning model is trained on the training dataset. Exemplary ML models include: recurrent neural networks (RNN), deep neural networks, other neural network architectures (e.g., fully connected, encoder-decoder, recursive neural network, uni- and bi-directional long-short term memory networks, gated recurrent unit network, convolutional), and/or other architectures such as support vector machines (SVM), logistic regression, linear classifier, time series classifier (e.g., ARIMA, SARIMA, SARIMAX, and exponential smoothing), k-nearest neighbor, decision trees, gradient boosting, random forest, and combinations of the aforementioned. Alternatively or additionally, where the term ML model is used herein, the ML model may be replaced and/or augmented with simpler non-ML model approaches, for example, sets of rules, mappings, and/or manual user adjustments. Optionally, the plant growing module and controller described herein may be used without the ML model and/or with the non-ML model approaches, for example, by a user manually setting the desired parameters described herein, and the controller maintaining the parameters within a tolerance range.

Referring now back to FIG. 3, a plant board 302C connects to cover 302A and/or casing 302B, as described herein, for example, as described with reference to FIG. 1. Computing device 310 may implement the methods described with reference to FIGS. 2A-2B, for example, by processor(s) 308 executing code 312A and/or 312B stored in a memory 312. A central computing device 310 may be associated with multiple plant growing modules 304. One or more centralized environment control system(s) 314 controlled by computing device 310 may adjust environmental parameters of multiple plant growing module(s) 304.

Controller 310 may generate instructions to control multiple environment control system(s). Alternatively or additionally, one or more environment control systems 314 included its own controller 310 that controls that respective environment control system, for example, based on sensor data associated with that respective environment control system. For example, air flow is controlled by an air flow system according to pressure sensors that sense interior of cover 302A and/or casing 302B.

Sensors 316A monitor interior of cover 302A. Exemplary sensors 316A include: air flow sensor, temperature sensor, concentration of oxygen sensor, concentration of carbon dioxide sensor, pressure sensor, illumination sensor, humidity sensor, air composition sensor, and air purity sensor, and/or an image sensor (e.g., visible light, infrared, multispectral).

Sensors 316B monitor interior of casing 302B. Exemplary sensors 316B include: temperature sensor, pressure sensor, illumination sensor, humidity sensor, contamination sensor, oxygen concentration sensor, carbon dioxide concentration sensor, irrigation water salinity sensor, water pH sensor, nutrient composition sensor, nutrient pH sensor, nutrient salinity sensor, and/or an image sensor (e.g., visible light, red/green/blue, thermal image, near infrared, far infrared, ultraviolet, for example, in the range of about 200 nanometers to about 2500 nanometers, for example, 400-700 nanometers, and/or multispectral).

Sensors 316C may monitor environment control system(s) 314 and/or monitor components connected and/or associated with environmental control system 314, for example, one or more of: sensors 316C may be located within the environment controls system 314 to monitor ECS 314, sensors 316C may be located at the inlets of ECS 314 to monitor inputs into the ECS 314, and/or sensors 316C may be located at the outlets of ECS 314 to monitor output of ECS 314.

Computing device 310 receives the measurements sensed by canopy sensors 316A and/or root sensors 316B, for example, via wires, over a wireless connection, via an internet of things (IoT) network connection, and/or over a network. Computing device 310 may independently monitor the environment within the interior of cover 302A via measurements obtained from sensor(s) 316A and/or independently monitor the environment within the interior of casing 302B via measurements obtained from sensor(s) 316B.

Exemplary values of parameters for the environment in interior of cover 302A include: Pressure about 30 Pascal-gauge, Temperature about 15-30 degrees Celsius, relative humidity about 35-80%, carbon dioxide concentration about 300-2000 parts per million (ppm), air changes about 20-300 per minute.

Exemplary values of parameters for the environment in interior of casing 302B include: Pressure about 15 Pascal-gauge, Temperature about 24 degrees Celsius, relative humidity about 90-100%, no light.

Exemplary environment control systems 314 (ECS) include air filtering system, irrigation system, air delivery system, temperature control system, air pressure control system, HVAC, and light control system. Optionally, one or more ECS 314 are set to control environment parameters of either interior of cover 302A, or interior of casing 302B, when the interiors of cover 302A and 302B are substantially isolated from one another and maintained at different settings, for example, different pressures, different light conditions, different airflows, and/or different temperatures.

Exemplary ECS 314 components that control at least one environment parameter of the interior of cover 302A (sometimes referred to herein as cover environment control system) and/or exemplary ECS 314 components that control at least one environment parameter of the interior of casing 302B (sometimes referred to herein as casing environment control system) include one or more of: air flow controller that controls air flow, heater that controls temperature, air conditioner that controls temperature, supplemental oxygen source that controls amount of oxygen in delivered air, supplemental carbon dioxide source that controls concentration of carbon dioxide in delivered air, humidifier that controls humidity in delivered air, light controller that controls illumination by lights, and a water adjustment system that controls composition and/or scheduling of delivered fluid.

Exemplary parameters of the environment of the interior of cover 302A (sometimes referred to herein as cover parameters) that are adjusted and/or scheduled by the respective ECS 314 components and/or computing device 310 include air flow, air change, temperature, concentration of oxygen, concentration of carbon dioxide, pressure, illumination, humidity, air composition, and air purity. Exemplary parameters of the environment of the interior of casing 302B (sometimes referred to herein as casing parameters) that are adjusted and/or scheduled by the respective ECS 314 components and/or computing device 310 include temperature, pressure, illumination, humidity, contamination, oxygen concentration, carbon dioxide concentration, irrigation water salinity, water pH, nutrient composition, nutrient pH, and nutrient salinity.

Computing device 310 may independently control the ECS 314 components that control cover parameters of the environment of interior of cover 302A, and/or independently control the ECS 314 components that control casing parameters of the environment of interior of casing 302B, for example, by adjusting one or more parameters of the respective ECS 314 components and/or scheduling of the respective ECS 314 components. For example, computing device 310 controls at least one air delivery parameter of air delivery and/or schedules different types of air delivery into interior of cover 302A by an air delivery system and/or controls at least one fluid delivery parameter and/or schedules different types of fluid delivery of a fluid delivery system that delivers fluid into interior of casing 302B.

The measurements sensed by canopy sensors 316A and/or root sensors 316B are inputted into ML model(s) 306, for obtaining an outcome indicative of values of the environment parameters predicted to generate a target profile in the plants growing in plant growing housing 304. Instructions are generated for maintaining and/or adjusting environment control system(s) 314 to provide the values of the environment parameters obtained from ML Model(s) 306.

Optionally, environment control system(s) includes an air delivery system operated according to instructions generated by computing device 310. Controller 310 may control air delivery system to maintain an air pressure within cover 302A above an air pressure of casing 302B and maintain the air pressure of the casing 302B above an ambient air pressure, for example, based on pressure values measured by pressure sensors sensing interior of cover 302A and/or interior of casing 302B. Alternatively or additionally, controller 310 may control air delivery system to deliver a pattern of airflow into the cover 302A, optionally via air inlet channels described herein. The pattern of airflow may be selected according to an association between a certain pattern of airflow and a target profile of plants exposed to the pattern of airflow, optionally as an output generated by an ML model 306, as described herein.

System 300 may include code instructions 312B for training ML model(s) 306 using training dataset 318A. Training code 312B may be stored in memory 312 and/or a data storage device 318. Alternatively, ML model(s) 306 is trained by another computing device (e.g., server 320) and transmitted to computing device 310 over a network 322 and/or remotely accessed by computing device 310 over network 322 (e.g., via a software interface for example, application programming interface (API), and/or software development kit (SDK)).

In yet another implementation, client terminal(s) 324 may act as a controller for adjusting environment control system 314. The ML model is executed by computing device 310, and the instructions for adjustment of environment control system 314 are locally generated by respective client terminals 324 (acting as the controller) that access a server implementation of computing device 310 to obtain the outcome of the ML model. In this manner, the ML model centrally computes, for each respective client terminal 324, the environment parameters to obtain the target profile of the plant (as described herein) grown at respective plant growing housings 304, and each respective client terminal 324 may locally generate its own set of instructions for its own associated environment control system 314.

Computing device 310 may be implemented as, for example, a client terminal, a server, a computing cloud, a virtual machine, a virtual server, a mobile device, a desktop computer, a thin client, a Smartphone, a Tablet computer, a laptop computer, a wearable computer, glasses computer, and a watch computer.

Multiple architectures of system 300 based on computing device 310 may be implemented. For example, computing device 310 may be integrated with plant growing housing 304, for example, computing device 310 is integrated within plant growing housing 304, for example, within the walls of plant growing housing 304 and/or as a box connected to the walls of plant growing housing 304. In another implementation, computing device 310 may be implemented as a dedicated device in communication with plant growing housing 304, for example, via a cable, a connector slot, a short range network, and/or a network 322. In another exemplary implementation, computing device 310 may be implemented as one or more servers (e.g., network server, web server, a computing cloud, a virtual server) that provides remote services to one or more plant growing housing 304 over network 322, and/or to remote client terminals 324 where each client terminal 324 is locally in communication with and/or is integrated with a respective plant growing housing 304. In yet another exemplary implementation, computing device 310 may be a device serving another purpose, on which code 312A is installed to provide controller functions, for example, a smartphone used by the grower.

Hardware processor(s) 308 may be implemented, for example, as a central processing unit(s) (CPU), a graphics processing unit(s) (GPU), field programmable gate array(s) (FPGA), digital signal processor(s) (DSP), and/or application specific integrated circuit(s) (ASIC). Processor(s) 308 may include one or more processors (homogenous or heterogeneous), which may be arranged for parallel processing, as clusters and/or as one or more multi core processors.

Memory 312 stores code instructions 312A and/or 312B executable by processor(s) 308. Memory 312 may be implemented as, for example, a random access memory (RAM), read-only memory (ROM), and/or a storage device, for example, non-volatile memory, magnetic media, semiconductor memory devices, hard drive, removable storage, and optical media (e.g., DVD, CD-ROM).

Optionally, computing device 310 includes and/or is in communication with a data storage device 318 for example, for storing ML model(s) 306, and/or for storing training dataset 318A for training ML model(s) 306. Data storage device 318 may be implemented as, for example, a memory, a local hard-drive, a removable storage device, an optical disk, a storage device, and/or as a remote server and/or computing cloud (e.g., accessed using a network connection). It is noted that code stored in data storage device 318 may be loaded into memory 312 for execution by processor(s) 308.

Optionally, computing device 310 is in communication with a user interface 328. User interface 328 may include a mechanism for the user to enter data (e.g., select the desired profile of the plant) and/or view data (e.g., the current environmental parameters), for example, a touch screen, a display, a mouse, a keyboard, and/or a microphone with voice recognition software. User interface 328 may include a graphical user interface (GUI) presented on a display.

Optionally, computing device 310 includes and/or is in communication with one or more network and/or data interfaces 350 for connecting to network 322 and/or to sensors 316A-C and/or to ECS 314, for example, one or more of, a network interface card, a wireless interface to connect to a wireless network, a physical interface for connecting to a cable for network connectivity, a virtual interface implemented in software, network communication software providing higher layers of network connectivity, and/or other implementations. Network and/or data interface 350 may be implemented, for example, as an internet of things (IOT) based full stack solution, a proprietary card integrates in its design cellular G3 G4 G5 transmission via SIM card. This enable each system 300 (e.g., device 310) to work and/or to be monitored independently (e.g., standalone) and directly to a computing cloud (e.g., server 320) regardless of its location in the world. In case of the failure in information transmission and in order to keep data integrity (e.g., note losing any data points), the system 300 (e.g., device 310) at the same location (e.g., facility) may automatically transmit the data to another (e.g., neighboring) system, where the neighboring system is utilized as a transmission point (redundancy). The data redundancy and/or redundancy of the controller (e.g., via the cloud and/or neighboring devices), at one or more locations, may meet GMP (good manufacturing practice) compliance and/or provide risk management, which requires data integrity and/or backup systems.

Computing device 310 may access a computing cloud (e.g., represented as server 320) over network 322, for example, to obtain code 312A and/or 312B and/or updates to the respective code. Computing device 3110 may communicate with computing cloud for other data transfer.

Network 322 may be implemented as, for example, the internet, a local area network, a virtual network, a wireless network, a cellular network, a local bus, a point to point link (e.g., wired), and/or combinations of the aforementioned.

Referring now back to FIGS. 4A-4B, FIG. 4A depicts components that deliver air to an interior of one or more covers. FIG. 4B depicts components that receive air from the interior of one or more covers.

Air delivery system 460 may act as a central air delivery system that delivers air to multiple covers.

FIGS. 4A and 4B depict air delivery system 460 operating in a closed loop mode, by circulating air in and out of one or more covers. Air is delivered and/or removed from covers, to enable control of the environment within the interior of the cover, for example, as described herein.

The air exiting from the cover may be circulated through heating and/or cooling batteries, for example, using water supplied from temperature controlled reservoirs for heating and/or cooling. Fresh air may enter circulation via activated carbon filters.

Air delivery system 460 is controlled by a controller, which may be, for example, an external device and/or integrated within the air delivery system. Air delivery system 460 may be, for example, a heating, ventilation and/or air conditioning (HVAC) device. Air delivery system 460 may control one or more of: sterility, humidity, temperature, air flow (e.g., air velocity), pressure, and/or carbon dioxide concentration.

As depicted in FIG. 4A, air delivery system 460 may be connected to one or more outlet tubes 470, for example, a single outlet tube.

As used herein, the term connect refers to providing fluid communication between the connected tubes for delivery of fluid, such as air and/or water and/or other irrigation fluid.

Outlet tube(s) 461 may be in fluid communication with a carbon dioxide (CO₂) source 466 and/or a humidifier source 467, which may be controlled by the controller and/or by the air delivery system. The concentration of carbon dioxide and/or percent humidity of the air being delivered to the interior of cover(s) may be controlled, for example, to obtain a target profile, and/or according to an outcome of the ML model, as described herein. Humidifier source 467 may control the relative humidity and/or be implemented as an air drying device. Alternatively or additionally, air drying is performed by the air delivery system 460.

Optionally, one or more filters 480 are positioned in the air channel pathway between air deliver system 460 and the air outlets of the plant board within the covers. Optionally, filter(s) 480 are positioned proximally to the CO₂ source 466 and/or a humidifier source 467, so that the humidification and/or CO₂ supply are added into filtered air. Filter(s) 480 may be, for example, HEPA filters, and/or ultraviolet (UV) lighting (e.g., for sterilization). The closed loop and/or filtering of the air reduces and/or prevents odors. Filters 480 may be designed for elimination of odor and/or removal of contamination.

Outlet tube(s) 461 may connect to an optional respective air inlet tube 462 associated with each cover. Each respective air inlet tube 462 may connect to an optional respective manifold 463. Each respective manifold 463 may connect to one or more air inlet channels 464 that connect to the cover. Each air inlet channel 464 includes a respective air opening into the interior of the cover, to direct the air (optionally with controlled CO₂ and/or humidity level) from air delivery system 460 into interior of cover.

As depicted in FIG. 4B, air conditioning unit may be connected to one or more air collection tubes 471 that receive air from interior of one or more covers, for example, a single air collection tube. The air collection tube(s) 471 may connect to one or more air outlet tubes 472 for each respective cover. Each air outlet tube 472 is connected to a respective air outlet located on the top portion of the cover, for receiving air from interior of cover.

Optionally, one or more filters 490 are positioned within the evacuation air channel that delivers air from the interior of cover to air delivery system 460. Filters may be for elimination of odor and/or removal of contaminants, for example, as described with reference to filters 480 of FIG. 4A.

Referring now back to FIG. 5, water supplied by fluid delivery system 560 may be water that has undergone reverse osmosis and/or sterilization. Optionally, the pH and/or salinity of the water is set and/or adjusted by the controller, for example, to obtain a target profile, as described herein.

Optionally, one or more filters 580 are positioned in the fluid channel pathway between fluid deliver system 560 and the fluid outlets of the plant board within the casings. Optionally, filter(s) 580 are positioned proximally to any components that adjust the water, for example, that adjust the pH and/or salinity of the water, so that filtered and/or sterilized water is adjusted. Filter(s) 580 may be, for example, HEPA filters, and/or ultraviolet (UV) lighting (e.g., for sterilization). The closed loop and/or filtering of the fluid reduces and/or prevents odors. Optionally, one or more filters 580 are positioned in the fluid evacuation channel that delivers fluid from the casing back to the fluid delivery system 560.

Fluid delivery system 560 may act as a central fluid delivery system that delivers fluid to multiple casings.

Fluid delivery system 560 operating in a closed loop mode, by circulating fluid in and out of one or more casings via fluid inlet channels, the casing and fluid outlets, as described herein. Fluid is delivered and/or removed from casings, to enable control of the environment within the interior of the casing, for example, as described herein.

Fluid delivery system 560 is controlled by a controller, which may be, for example, an external device and/or integrated within the air delivery system. Fluid delivery system 460 may be, for example, a pump.

Fluid delivery system 560 may be operated, for example, a high and/or low pressure aeroponic (e.g. fog) mode, and/or Nutrient Film Technology (NFT) mode.

Fluid delivery system 560 may be connected to one or more central inlet irrigation tubes 540, for example, a single tube that delivers fluid from fluid delivery system 560 towards the casing(s). The central inlet irrigation tube(s) 540 may connect to one or more optional fluid tubes 541, where each respective casing is associated with a respective one or more fluid tubes 541. Each respective fluid tube 541 may be connected to an optional manifold 542. Each respective casing may be associated with a respective manifold 542. One or more fluid inlet channel 543, each with one or more irrigation feeders 550, may be connected with each manifold 542. Fluid inlet channels 543 may be arranged in parallel to one another along plant board 544. Fluid inlet channels 543 may be integrated with plant board 544 into a monolithic structure, for example, as described herein.

Optionally, drainage fluid from the casing(s) is drained via one or more drainage tubes, which may cycle the drainage fluid back to fluid delivery system 560.

Referring now back to FIG. 6, monolithic plant board 652 may be made, for example, by injection molding techniques, casting, precision manufacturing, 3D printing, and/or other approaches designed to create monolithic structures. The monolithic design of the plant board enables precise placement of the components on the board (e.g., air inlet channels, fluid channels, sensors, irrigation feeders) where the location of the components on the board cannot be changed. The precise location of the components of the board increased the ability of controlling the growing conditions of the plants growing on the board, to obtain reproducible and/or precise growing conditions, to obtain a reproducible target profile, as described herein.

600A depicts a top view of board 652, 600B depicts a side view of monolithic plant board 652, and 600C depicts a front view of monolithic plant board 652. The top surface of the monolithic plant board 652 may be sized and/or shaped for enclosing and sealing a bottom side of a cover, as described herein. The bottom surface of the plant board may be sized and/or shaped for enclosing and sealing a top side of a casing, as described herein.

Monolithic plant board 652 has a thickness (as seen in side view 600B and/or top view 600C), a top surface (as seen in top view 600A), a bottom surface, and multiple apertures 670 each sized and shaped to accommodate a stalk of a plant.

Different arrangement of the monolithic plant board 652 include, for example:

A fully-monolithic arrangement, in which plant board 652 includes all of:

(i) Multiple air inlet air inlet channels 653 having openings facing upwards located on the top side of the monolithic plant board 652, as described herein. Air inlet channels 653 may be designed to provide laminar air flow, as described herein.

(ii) Multiple fluid channels 650 optionally including irrigation feeders 651 for delivering a fluid. Fluid channels 650 and/or irrigation feeder 651 are located on the bottom side of the monolithic plant board 652. The opening of the fluid channels 650 and/or the irrigation feeders 651 are facing downwards when monolithic plant board 652 is attached to the casing, towards roots of plants located therein.

(iii) Sensors 670A located on the top side of monolithic plant board 652. Sensors 670A may be for monitoring an interior of a cover when the cover is attached to the monolithic plant board 652, as described herein. Exemplary sensors 670A are described herein.

(iv) Sensors 670B located on the bottom side of monolithic plant board 652. Sensors 670B may be for monitoring an interior of a casing when the casing is attached to the monolithic plant board 652, as described herein. Exemplary sensors 670B are described herein.

A semi-monolithic arrangement, in which plant board 652 includes (i), and excludes (ii), (iii), and (iv).

Another semi-monolithic arrangement, in which plant board 652 includes (i) and (ii), and excludes (iii), and (iv).

Yet another semi-monolithic arrangement, in which plant board 652 includes (ii), and excludes (i), (iii), and (iv).

In the semi-monolithic arrangements, the components excluded from the monolithic plant board may be connected to the monolithic plant board, for example, by screws and/or quick connectors. The semi-monolithic arrangements may provide customization of the component excluded from the monolithic board, for example, the same monolithic plant board may be re-used for different plant types by selecting some customized components.

Optionally, air inlet channels 653 and/or fluid channels 650 may be located on the respective top and/or bottom surface of the board. Alternatively or additionally, air inlet channels 653 and/or fluid channels 650 may be located within a thickness of the board and/or a respective top thickness and/or bottom thickness of the board. In such implementation, the surface of the board may be substantially smooth. For example, the thickness of the plant board may be about 3-5 centimeters (cm), or about 1-5 cm, or about 2-4 cm or other values. The diameter of the air inlet channels 653 may be, for example, about 1-3 cm, or about 2-3 cm, or about 1-5 cm, or other values, optionally selected to deliver a sufficient amount of laminar air flow. Air inlet channels 653 may connect to a larger central air tube (e.g., about 10-20 cm, or 15-20 cm, or other value) connected to the air supply system, as described herein. Air inlet channels 653 and/or fluid channels 650 and/or apertures may be arranged in parallel, for example, an air inlet channel 653 is located at an upper portion of the board, running in parallel relative to a thickness of the board to a fluid channel 650 located at the bottom portion of the board, which are located in parallel along the surface of the board to multiple apertures designed to accommodate the plants.

Referring now back to FIG. 7, each plant growing module 770 includes at least a plant board, a cover, and a casing, as described herein. Controller 702 may control one or more central environmental systems (e.g., air delivery system, fluid delivery system, lighting system, as described herein) controlling environmental parameters (e.g., air delivery, fluid delivery, lights 760) to the plant growing modules 770 within set 750.

Optionally, multiple plant growing modules 770 are located on a common racking system. Plant growing modules 770 may be arranged, for example, horizontally and/or vertically.

Each module 770 may a standalone module, and/or part of a set 750 of modules 770, located indoors, for example, in a greenhouse. The indoor implementation may utilize solely artificial lighting both for photosynthesis and/or photoperiodicity in a climate-controlled environment, as described herein, in order to provide accurate control of the lighting as opposed to sunshine which cannot be predicted and/or controlled, optionally to obtain the target profile, as described herein. The greenhouse implementation may use solar lighting for photosynthesis and/or either complementary low-intensity lighting or darkening system to control photoperiodicity and adjust according to the current available solar lighting to provide target lighting, optionally to obtain the target profile, as described herein.

The number of plant growing modules 770 in each set may be, for example, about 1-10, or 3-7, or other numbers.

The volume of each plant growing module 770 may be, for example, about 1 cubic meter, or about 0.5-2 cubic meters, or other values. The total volume per set 750 may be, for example, about 3-10, or about 5-7 cubic meters, or other values.

Optionally, plants from a common genetic source are grown in each of the multiple plant growing modules 770. Controller 702 may adjust the central environmental system(s) to control the environmental parameter for the plants of the common genetic source in the multiple plant growing modules 770 to obtain a common target profile.

Referring now back to FIG. 8, a single set 750 of plant growing modules is described, for example, with reference to FIG. 7. The multiple sets 750 may be stored on a common racking system. Each set 750 may grow, plants from a common genetic source.

It is expected that during the life of a patent maturing from this application many relevant controllers will be developed and the scope of the term controller is intended to include all such new technologies a priori.

As used herein the term “about” refers to ±10%.

The terms “comprises”, “comprising”, “includes”, “including”, “having” and their conjugates mean “including but not limited to”.

The term “consisting of” means “including and limited to”.

The term “consisting essentially of” means that the composition, method or structure may include additional ingredients, steps and/or parts, but only if the additional ingredients, steps and/or parts do not materially alter the basic and novel characteristics of the claimed composition, method or structure.

As used herein, the singular form “a”, “an” and “the” include plural references unless the context clearly dictates otherwise. For example, the term “a compound” or “at least one compound” may include a plurality of compounds, including mixtures thereof.

Throughout this application, various embodiments of this invention may be presented in a range format. It should be understood that the description in range format is merely for convenience and brevity and should not be construed as an inflexible limitation on the scope of the invention. Accordingly, the description of a range should be considered to have specifically disclosed all the possible subranges as well as individual numerical values within that range. For example, description of a range such as from 1 to 6 should be considered to have specifically disclosed subranges such as from 1 to 3, from 1 to 4, from 1 to 5, from 2 to 4, from 2 to 6, from 3 to 6 etc., as well as individual numbers within that range, for example, 1, 2, 3, 4, 5, and 6. This applies regardless of the breadth of the range.

Whenever a numerical range is indicated herein, it is meant to include any cited numeral (fractional or integral) within the indicated range. The phrases “ranging/ranges between” a first indicate number and a second indicate number and “ranging/ranges from” a first indicate number “to” a second indicate number are used herein interchangeably and are meant to include the first and second indicated numbers and all the fractional and integral numerals therebetween.

It is appreciated that certain features of the invention, which are, for clarity, described in the context of separate embodiments, may also be provided in combination in a single embodiment. Conversely, various features of the invention, which are, for brevity, described in the context of a single embodiment, may also be provided separately or in any suitable subcombination or as suitable in any other described embodiment of the invention. Certain features described in the context of various embodiments are not to be considered essential features of those embodiments, unless the embodiment is inoperative without those elements.

In addition, any priority document(s) of this application is/are hereby incorporated herein by reference in its/their entirety.

1. A system for controlled and sterile plant growth, comprising:
a plant board comprising a plurality of apertures sized and shaped to accommodate a stalk of a plant;
a cover sized and shaped to enclose and seal a top side of the plant board for maintaining sterility of an interior of the cover;
a plurality of air outlets located on a top portion of the cover;
a casing sized and shaped to enclose and seal a bottom of the plant board for maintaining sterility of an interior of the casing;
a plurality of air inlet channels having openings facing upwards located on the top side of the plant board, the plurality of air inlet channel are designed to provide laminar air flow into an interior of the cover;
wherein the plurality of apertures are sized and shaped to provide air flow from the cover to the casing when accommodating the stalk of the plant; and
a controller that controls an air delivery system to maintain an air pressure within the cover above an air pressure of the casing and maintain the air pressure of the casing above an ambient air pressure.

2. The system of claim 1, further comprising:
at least one filter for elimination of odor and/or removal of contamination, the at least one filter is connected to the air outlets outside the cover within an evacuation air channel of air exiting from an interior of the cover, and/or connected to the air inlet channels, before entering the cover within an entering air channel of air being delivered to the interior of the cover.

3. The system of claim 1, further comprising:
a removable sampling cassette with contamination capturing apparatus that captures a sample of contaminants in the interior of the casing and/or the interior of the cover indicating a failure in maintaining sterility therein.

4. The system of claim 1, further comprising a low-pressure discharge valve located within the casing, the low-pressure discharge valve set at a pressure between an ambient air pressure and a target air pressure of the interior of the cover.

5. The system of claim 1, wherein the air delivery system is operating in a closed loop mode, by circulating air within the plurality of air inlet channels, the cover, and the plurality of air outlets.

6. The system of claim 5, further comprising a plurality of covers, associated plurality of plant boards, and associated plurality of casings, the air delivery system in communication with a respective plurality of air inlet channels and plurality of air outlets of each of the plurality of covers, wherein a single air delivery system includes a single air outlet tube connected to the plurality of air outlets of each of the plurality of covers, the single air delivery system including a single air inlet tube connected to each of the plurality of air outlets of the plurality of covers.

7. (canceled)

8. The system of claim 5, wherein the air deliver system is set to deliver a pattern of airflow into the cover via the plurality of air inlet channels, the pattern of airflow selected according to an association between the pattern of airflow and a target profile of a target type of plant exposed to the pattern of airflow, wherein the target profile includes at least one member selected from a group consisting of: a target biology of the target type of plant, a target physiology of the target type of plant, and a target morphology of the target type of plant, and wherein one or more of:
(i) the target type of plant is selected from a group consisting of: cannabis, transgenic plants, vegetables, green leaves, and vanilla,
(ii) the target biology is selected from a group consisting of protein expression, hormone expression, and chemical profile,
(iii) the target physiology is selected from a group consisting of: transpiration, growth rate, yield, and apical control, plant shape, size, leaf number, and number of branches.

9-10. (canceled)

11. The system of claim 1, wherein a spacing and/or a number and/or a pattern of location of the plurality of air inlet channels is selected according to a prediction that plants of a target type exposed to the pattern of airflow from the spacing and/or a number and/or a pattern of spacing of the plurality of air inlet channels obtain a target profile.

12. (canceled)

13. The system of claim 1, further comprising a plurality of fluid inlet channels having irrigation feeders for delivering a fluid, the plurality of fluid channels are located on the bottom side of the plant board and the opening of the plurality of fluid inlet channel are facing downwards, and a fluid outlet located on a bottom of the casing.

14. The system of claim 1, further comprising a plurality of fluid inlet channels having irrigation feeders for delivering a fluid, the plurality of fluid inlet channels are located within an inner surface of the casing and the opening of the plurality of fluid inlet channel are facing upwards, and a fluid outlet located on a bottom of the casing.

15. The system of claim 14, further comprising a fluid delivery system in communication with the plurality of fluid channels and the fluid outlet, the fluid delivery system operating in a closed loop mode, by circulating fluid within the plurality of fluid inlet channels, the casing, and the fluid outlet, a plurality of covers, associated plurality of plant boards, and associated plurality of casings, the fluid delivery system in communication with a respective plurality of fluid inlet channels and plurality of fluid outlets of each of the plurality of casings, wherein a single fluid delivery system includes a single fluid outlet tube connected to the plurality of fluid inlet channels of each of the plurality of casings, the single fluid delivery system including a single fluid inlet tube connected to each fluid outlet of the plurality of casings.

16-17. (canceled)

18. The system of claim 14, wherein a spacing and/or a number and/or a pattern of spacing of the plurality of fluid inlet channels is selected according to an association between the spacing and/or a number and/or a pattern of spacing of the plurality of fluid inlet channels and a target profile of plants exposed to fluid delivered by the fluid inlet channels.

19. The system of claim 1, further comprising: a first set of cover sensors located within the cover for monitoring an interior of the cover, and a second set of casing sensors located within the casing for monitoring an interior of the casing, and a controller for independently monitoring the environment within the cover using data obtained from the first set of sensors, and independently monitoring the environment within the casing using data obtained from the second set of sensors, and further comprising a plurality of covers, associated plurality of plant boards, and associated plurality of casings, connected to a central air delivery system and/or a central fluid delivery system, and further comprising a third set of sensors for monitoring at the central air delivery system and/or the central fluid delivery system located at the inlets and/or outlets of the central air delivery system and/or the central fluid delivery system.

20. The system of claim 19, wherein the controller independently controls a plurality of cover parameters of at least one cover environment control system for controlling the environment within the cover according to the monitored first set of sensors, controls a plurality of casing parameters of at least one casing environment control system for controlling the environment within the casing according to the monitored second set of sensors, and controls at least one air delivery parameter of the central air delivery system and/or controls at least one fluid delivery parameter of the central fluid delivery system, wherein the at least one air delivery parameter includes scheduling of different types of air delivery, and the at least one fluid delivery parameter includes scheduling of different types of fluid delivery.

21. The system of claim 20, wherein at least one of:
(i) the at least one cover environment control system and the at least one casing environment control system are selected from a group consisting of: air flow controller that controls air flow, heater that controls temperature, air conditioner that controls temperature, supplemental oxygen source that controls amount of oxygen in delivered air, supplemental carbon dioxide source that controls concentration of carbon dioxide in delivered air, humidifier that controls humidity in delivered air, light controller that controls illumination by lights, and a water adjustment system that controls composition and/or scheduling of delivered fluid,
(ii) the plurality of cover parameters are selected from a group consisting of: air flow, air change, temperature, concentration of oxygen, concentration of carbon dioxide, pressure, illumination, humidity, air composition, and air purity and the plurality of casing parameters are selected from a group consisting of: temperature, pressure, illumination, humidity, contamination, oxygen concentration, carbon dioxide concentration, irrigation water salinity, water pH, nutrient composition, nutrient pH, and nutrient salinity,
(iii) the first set of sensors are selected from a group consisting of: temperature, humidity, carbon dioxide, air pressure, imaging, and light intensity, and the second set of sensors are selected from a group consisting of: temperature, humidity, air pressure, and irrigation flowrate, and
(iv) the first set of sensors are located on the top side of the board and the second set of sensors are located on the bottom side of the board.

22-25. (canceled)

26. The system of claim 1, wherein the casing includes an elongated indentation along at least a portion of an internal perimeter thereof, the elongated indentation sized and shaped to accommodate a thickness of the plant board, and to enable insertion and removal of the plant board from the cover.

27-28. (canceled)

29. The system of claim 1, wherein the cover is made of a non-rigid material that forms a predefined shape when an air pressure within the cover is set to a target air pressure above an air pressure within the casing and above an ambient air pressure, and the cover is designed to collapse from the predefined shape when the air pressure therein is below the ambient air pressure.

30. A monolithic plant board for controlled plant growth, comprising:
the monolithic plant board having a thickness, a top surface, a bottom surface, and a plurality of apertures each sized and shaped to accommodate a stalk of a plant;
the top surface of the monolithic plant board sized and shaped for enclosing and sealing a bottom side of a cover for maintain sterility of an interior of the cover;
the bottom surface of the plant board sized and shaped for enclosing and sealing a top side of a casing for maintain sterility of an interior of the casing;
a plurality of air inlet channels integrated within the monolithic plant board, the plurality of air inlet channels having openings facing upwards located on the top side of the plant board, the plurality of air inlet channel are designed to provide laminar air flow into an interior of the cover;
a first set of sensors for monitoring an interior of the cover, the first set of sensors are located on the top side of the monolithic plant board and integrated within the monolithic plant board; and
a second set of sensor for monitoring an interior of the casing, the second set of sensors are located on the bottom side of the monolithic plant board and integrated within the monolithic plant board.

31-32. (canceled)

33. The monolithic plant board of claim 30, wherein a spacing and/or a number and/or a pattern of location of the plurality of air inlet channels of the monolithic plant board is selected according to a prediction that plants of a target type exposed to the pattern of airflow from the spacing and/or a number and/or a pattern of spacing of the plurality of air inlet channels obtain a target profile.

34. A monolithic plant board for controlled plant growth, comprising:
the monolithic plant board having a thickness, a top surface, a bottom surface, and a plurality of apertures each sized and shaped to accommodate a stalk of a plant;
the top surface of the monolithic plant board sized and shaped for enclosing and sealing a bottom side of a cover for maintain sterility of an interior of the cover;
the bottom surface of the monolithic plant board sized and shaped for enclosing and sealing a top side of a casing for maintain sterility of an interior of the casing; and
a plurality of fluid channels having irrigation feeders for delivering a fluid, the plurality of fluid channels are located on the bottom side of the monolithic plant board and the opening of the plurality of fluid channel are facing downwards towards roots of plants located below the monolithic plant board in the interior of the casing; and
at least one sensor for monitoring an interior of the casing, the second set of sensors are located on the bottom side of the monolithic plant board and integrated within the monolithic plant board.

35-39. (canceled)
